(19) United States
(12) Patent Application Publication
(10) Pub. No.: US 2026/0106122 A1
(43) Pub. Date: Apr. 16, 2026

(54) DRY CHAMBER CLEAN USING THERMAL AND PLASMA PROCESSES

(71) Applicant: Lam Research Corporation, Fremont, CA (US)

(72) Inventors: Boris VOLOSSKIY, San Jose, CA (US); Shambhu KC, Fremont, CA (US); Chen WANG, Fremont, CA (US); Andrew Pratheep LUSHINGTON, Sunnyvale, CA (US); Michael Thomas MYERS, Tualatin, OR (US); Timothy William WEIDMAN, Sunnyvale, CA (US); Jeremy Todd TUCKER, Redwood City, CA (US); Daniel PETER, Sunnyvale, CA (US); Samantha S.H. TAN, Newark, CA (US); Jerome S. HUBACEK, Fremont, CA (US); Alan J. JENSEN, Mountain House, CA (US); Jothilingam RAMALINGAM, Milpitas, CA (US); Richard WISE, Los Gatos, CA (US); Jason STEVENS, Oakland, CA (US); Seng ONG, Newark, CA (US); Shahd Hassan LABIB, San Jose, CA (US); Yoko YAMAGUCHI, Union City, CA (US)

(21) Appl. No.: 19/116,865

(22) PCT Filed: Oct. 5, 2023
(86) PCT No.: PCT/US2023/034545

§ 371 Date: Mar. 28, 2025

Related U.S. Application Data
(60) Provisional application No. 63/378,793, filed on Oct. 7, 2022.

(51) Int. Cl. H01J 37/32; G03F 7/004; G03F 7/16

(52) U.S. Cl. CPC H01J 37/32862; G03F 7/0043; G03F 7/168; H01J 37/32357

(57) ABSTRACT

A metal-containing photoresist film may be deposited on a semiconductor substrate. Unintended metal-containing material may form on internal surfaces of a process chamber during deposition, bevel and backside cleaning, exposure, baking, development, etch, or other photolithography operations. A dry chamber clean may remove some of the unintended metal-containing material by exposure to plasma. A dry chamber clean may remove some of the unintended metal-containing material and modify some of the unintended metal-containing material by exposure to an etch gas at an elevated temperature without striking a plasma. The dry chamber clean may remove the modified metal-containing material using plasma having a chemistry configured to form volatile products of the modified metal-containing material. In some embodiments, the plasma includes a halide-containing plasma, hydrogen-containing plasma, hydrocarbon-containing plasma, inert gas-containing plasma, or mixtures thereof.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

The present disclosure relates to removal of photoresist material in semiconductor fabrication, and more particularly to chamber clean of metal-containing photoresist material in semiconductor fabrication.

### BACKGROUND

The fabrication of semiconductor devices, such as integrated circuits, is a multi-step process involving photolithography. In general, the process includes the deposition of material on a wafer, and patterning the material through lithographic techniques to form structural features (e.g., transistors and circuitry) of the semiconductor device. The steps of a typical photolithography process known in the art include: preparing the substrate; applying a photoresist, such as by spin coating; exposing the photoresist to light in a desired pattern, causing the exposed areas of the photoresist to become more or less soluble in a developer solution; developing by applying a developer solution to remove either the exposed or the unexposed areas of the photoresist; and subsequent processing to create features on the areas of the substrate from which the photoresist has been removed, such as by etching or material deposition.

The evolution of semiconductor design has created the need, and has been driven by the ability, to create ever smaller features on semiconductor substrate materials. This progression of technology has been characterized in “Moore's Law” as a doubling of the density of transistors in dense integrated circuits every two years. Indeed, chip design and manufacturing has progressed such that modern microprocessors may contain billions of transistors and other circuit features on a single chip. Individual features on such chips may be on the order of 22 nanometers (nm) or smaller, in some cases less than 10 nm.

One challenge in manufacturing devices having such small features is the ability to reliably and reproducibly create photolithographic masks having sufficient resolution. Current photolithography processes typically use 193 nm ultraviolet (UV) light to expose a photoresist. The fact that the light has a wavelength significantly greater than the desired size of the features to be produced on the semiconductor substrate creates inherent issues. Achieving feature sizes smaller than the wavelength of the light requires use of complex resolution enhancement techniques, such as multipatterning. Thus, there is significant interest and research effort in developing photolithographic techniques using shorter wavelength light, such as extreme ultraviolet radiation (EUV), having a wavelength of from 10 nm to 15 nm, e.g., 13.5 nm.

EUV photolithographic processes can present challenges, however, including low power output and loss of light during patterning. Traditional organic chemically amplified resists (CAR) similar to those used in 193 nm UV lithography have potential drawbacks when used in EUV lithography, particularly as they have low absorption coefficients in EUV region and the diffusion of photo-activated chemical species can result in blur or line edge roughness. Furthermore, in order to provide the etch resistance required to pattern underlying device layers, small features patterned in conventional CAR materials can result in high aspect ratios at risk of pattern collapse. Accordingly, there remains a need for improved EUV photoresist materials, having such properties as decreased thickness, greater absorbance, and greater etch resistance.

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

### SUMMARY

Provided herein is a method of cleaning a process chamber. The method includes providing, in the process chamber, a semiconductor substrate with a metal-containing resist film on a surface of the semiconductor substrate, wherein organometallic material is formed on one or more internal surfaces of the process chamber. The method further includes exposing, without the semiconductor substrate in the process chamber, the one or more internal surfaces of the process chamber to a non-plasma etch gas in the process chamber to remove first portions of the organometallic material. The method further includes exposing, without the semiconductor substrate in the process chamber, the one or more internal surfaces of the process chamber to a first plasma to remove second portions of the organometallic material.

In some implementations, exposing the one or more internal surfaces to the non-plasma etch gas converts unremoved portions of the organometallic material to a nonvolatile byproduct, where the second portions comprise the nonvolatile byproduct. In some implementations, the first plasma includes a halide-containing plasma, a hydrogen-containing plasma, a hydrocarbon-containing plasma, an inert gas-containing plasma, or a combination thereof. In some implementations, the first plasma comprises a chlorine (Cl₂) plasma. In some implementations, the non-plasma etch gas includes a hydrogen halide, boron tribromide, boron trichloride, or combinations thereof. In some implementations, the non-plasma etch gas comprises hydrogen chloride (HCl) or hydrogen bromide (HBr). In some implementations, introducing the non-plasma etch gas comprises: heating the one or more internal surfaces of the process chamber to an elevated temperature, wherein the elevated temperature is between about −15° C. and about 200° C., and flowing the non-plasma etch gas into the process chamber. In some implementations, the method further includes exposing the one or more internal surfaces of the process chamber to a second plasma to remove one or both of residual gases and residual organic material from the process chamber. In some implementations, the second plasma includes an oxygen-containing plasma or hydrogen-containing plasma. In some implementations, the first plasma is configured to form volatile products with the second portions of the organometallic material. In some implementations, the method further includes generating the first plasma in a remote plasma source coupled to the process chamber. In some implementations, the method further includes generating the first plasma directly in the process chamber. In some implementations, the metal-containing resist film comprises a metal oxide-containing EUV photoresist material. In some implementations, the organometallic material includes at least tin oxide. In some implementations, providing the semiconductor substrate includes depositing the metal-containing resist film on the surface of the semiconductor substrate in the process chamber. In some implementations, providing the semiconductor substrate includes baking the metal-containing resist film on the surface of the semiconductor substrate in the process chamber. In some implementations, providing the semiconductor substrate includes dry developing the metal-containing resist film on the surface of the semiconductor substrate in the process chamber.

Also provided herein is a method of cleaning a process chamber. The method includes providing, in the process chamber, a semiconductor substrate with a metal-containing resist film on a surface of the semiconductor substrate, wherein organometallic material is formed on one or more internal surfaces of the process chamber. The method further includes exposing, without the semiconductor substrate in the process chamber, the one or more internal surfaces of the process chamber to a first plasma in the process chamber to remove first portions of the organometallic material. The method further includes exposing, without the semiconductor substrate in the process chamber, the one or more internal surfaces of the process chamber to a non-plasma etch gas to remove second portions of the organometallic material.

In some implementations, exposing the one or more internal surfaces to the first plasma converts unremoved portions of the organometallic material to a nonvolatile byproduct, where the second portions comprise the nonvolatile byproduct.

Also provided herein is a method of cleaning a process chamber. The method includes providing, in the process chamber, a semiconductor substrate with a metal-containing resist film on a surface of the semiconductor substrate, wherein organometallic material is formed on one or more internal surfaces of the process chamber. The method further includes exposing, without the semiconductor substrate in the process chamber, the one or more internal surfaces of the process chamber to a first plasma in the process chamber to remove at least a substantial portion of the organometallic material.

In some implementations, the first plasma comprises a halide-containing plasma, a hydrogen-containing plasma, a hydrocarbon-containing plasma, an inert gas-containing plasma, or a combination thereof. In some implementations, the first plasma includes Cl₂, CH₄, Ar, or a mixture thereof. In some implementations, the first plasma includes HBr, Ar, or a mixture thereof. In some implementations, a chamber pressure of the process chamber during exposure to the first plasma is between about 1 mTorr and about 20 Torr. In some implementations, the method further includes exposing, without the semiconductor substrate in the process chamber, the one or more internal surfaces of the process chamber to a second plasma to remove one or both of residual gases and residual organic material from the process chamber.

Also provided herein is an apparatus for cleaning a process chamber. The apparatus includes a process chamber with a substrate support, where the substrate support is configured to support a semiconductor substrate comprising a metal-containing resist film formed on a surface of the semiconductor substrate, a vacuum line coupled to the process chamber, and a gas line coupled to the process chamber. The apparatus further includes a controller configured with instructions for performing the following operations: provide, in the process chamber, the semiconductor substrate, where organometallic material is formed on one or more internal surfaces of the process chamber, expose, without the semiconductor substrate in the process chamber, the one or more internal surfaces of the process chamber to a non-plasma etch gas to remove first portions of the organometallic material, and expose, without the semiconductor substrate in the process chamber, the one or more internal surfaces of the process chamber to a first plasma to remove second portions of the organometallic material.

In some implementations, the apparatus further includes a remote plasma source fluidly coupled to the process chamber, where the first plasma is generated in the remote plasma source. In some implementations, the first plasma is generated directly in the process chamber. In some implementations, the process chamber is selected from one of the following groups: a dry deposition chamber, a bevel edge and/or backside clean chamber, a bake chamber, or a dry development chamber. In some implementations, the controller configured with instructions to expose the one or more internal surfaces to the non-plasma etch gas is configured with instructions to expose the one or more internal surfaces to the non-plasma etch gas to convert unremoved portions of the organometallic material to a nonvolatile byproduct, wherein the second portions comprise the nonvolatile byproduct. In some implementations, the first plasma includes a halide-containing plasma, hydrogen-containing plasma, hydrocarbon-containing plasma, inert gas-containing plasma, or combination thereof, where the non-plasma etch gas includes a hydrogen halide, hydrogen and halogen gas, boron trichloride, or combinations thereof, and where the organometallic material comprises at least tin oxide.

Also provided herein is an apparatus for cleaning a process chamber. The apparatus includes a process chamber with a substrate support, where the substrate support is configured to support a semiconductor substrate comprising a metal-containing resist film formed on a surface of the semiconductor substrate, a vacuum line coupled to the process chamber, and a gas line coupled to the process chamber. The apparatus further includes a controller configured with instructions for performing the following operations: provide, in the process chamber, the semiconductor substrate, wherein organometallic material is formed on one or more internal surfaces of the process chamber, expose, without the semiconductor substrate in the process chamber, the one or more internal surfaces of the process chamber to a first plasma to remove first portions of the organometallic material, and expose, without the semiconductor substrate in the process chamber, the one or more internal surfaces of the process chamber to a non-plasma etch gas to remove second portions of the organometallic material.

In some implementations, the apparatus further includes a remote plasma source fluidly coupled to the process chamber, wherein the first plasma is generated in the remote plasma source. In some implementations, the first plasma is generated directly in the process chamber. In some implementations, the process chamber is selected from one of the following: a dry deposition chamber, a bevel edge and/or backside clean chamber, a bake chamber, or a dry development chamber. In some implementations, the controller configured with instructions to expose the one or more internal surfaces to the first plasma is configured with instructions to expose the one or more internal surfaces to the first plasma to convert unremoved portions of the organometallic material to a nonvolatile byproduct, where the second portions comprise the nonvolatile byproduct. In some implementations, the first plasma includes a halide-containing plasma, hydrogen-containing plasma, hydrocarbon-containing plasma, or combination thereof, where the non-plasma etch gas includes a hydrogen halide, hydrogen and halogen gas, boron trichloride, or combinations thereof, and where the organometallic material includes at least tin oxide.

Also provided herein is an apparatus for cleaning a process chamber. The apparatus includes a process chamber with a substrate support, where the substrate support is configured to support a semiconductor substrate comprising a metal-containing resist film formed on a surface of the semiconductor substrate, a vacuum line coupled to the process chamber, and a gas line coupled to the process chamber. The apparatus further includes a controller configured with instructions for performing the following operations: provide, in the process chamber, the semiconductor substrate, wherein organometallic material is formed on one or more internal surfaces of the process chamber, and expose, without the semiconductor substrate in the process chamber, the one or more internal surfaces of the process chamber to a first plasma to remove at least a substantial portion of the organometallic material.

In some implementations, the first plasma includes a halide-containing plasma, hydrogen-containing plasma, hydrocarbon-containing plasma, inert gas-containing plasma, or combination thereof, and wherein the organometallic material comprises at least tin oxide.

### BRIEF DESCRIPTION OF DRAWINGS

FIG. 1 presents a flow diagram of an example method for depositing and developing a metal-containing photoresist according to some implementations.

FIG. 2A presents a flow diagram of an example method of performing a dry chamber clean using thermal and plasma processes according to some implementations.

FIG. 2B presents a flow diagram of an alternative example method of performing a dry chamber clean using plasma and thermal processes according to some implementations.

FIGS. 3A-3F show cross-sectional schematic illustrations of a process chamber undergoing various processing stages of dry chamber clean using thermal and plasma processes according to some implementations.

FIGS. 4A-4D show cross-sectional schematic illustrations of various processing stages for removal of a metal-containing EUV photoresist material from chamber walls of a process chamber according to some implementations.

FIG. 5 depicts a schematic illustration of an example process station that is suitable for maintaining a low-pressure environment that is suitable for performing the methods in accordance with certain disclosed embodiments.

FIG. 6 depicts a schematic illustration of an example multi-station processing tool suitable for implementation of various operations in accordance with certain disclosed embodiments.

FIG. 7 shows a cross-sectional schematic view of an example inductively-coupled plasma apparatus for implementing certain implementations and operations described herein.

FIG. 8 depicts a semiconductor process cluster tool architecture with vacuum-integrated deposition and patterning modules that interface with a vacuum transfer module, suitable for implementations of processes described herein.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

This disclosure relates generally to the field of semiconductor processing. In particular aspects, the disclosure is directed to processes and apparatuses for processing of photoresists (e.g., EUV-sensitive metal and/or metal oxide-containing photoresists), for example to remove metal oxide-containing material from a process chamber in the context of EUV patterning or other wavelength patterning. While discussion below may be focused on EUV photoresists, it will be apparent that the photoresists discussed herein may also be appropriate for use with other wavelengths of radiation, and the techniques and apparatuses discussed herein are not limited solely to EUV photoresist manufacturing.

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

### INTRODUCTION

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

EUV lithography makes use of EUV resists that are patterned to form masks for use in etching underlying layers. EUV resists may be polymer-based chemically amplified resists (CARs) produced by liquid-based spin-on techniques. An alternative to CARs is directly photopatternable metal oxide-containing films, such as those available from Inpria, Corvallis, OR, and described, for example, in US Patent Publications US 2017/0102612, US 2016/021660 and US 2016/0116839, incorporated by reference herein at least for their disclosure of photopatternable metal oxide-containing films. Such films may be produced by spin-on techniques or dry vapor-deposited. The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled “EUV PHOTOPATTERNING OF VAPOR-DEPOSITED METAL OXIDE-CONTAINING HARDMASKS,” and/or in International Patent Application No. PCT/US2019/31618, filed May 9, 2019, and titled “METHODS FOR MAKING EUV PATTERNABLE HARD MASKS,” the disclosures of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

It should also be understood that the while present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. The specific methods may depend on the particular materials and applications used in the semiconductor substrate and ultimate semiconducting device. Thus, the methods described in this application are merely exemplary of the methods and materials that may be used in present technology.

These directly photopatternable EUV resists may be composed of or contain high-EUV-absorbance metals and their organometallic oxides/hydroxides and other derivatives. Upon EUV exposure, EUV photons as well as secondary electrons generated can induce chemical reactions, such as beta-H elimination reaction in SnOx-based resist (and other metal oxide-based resists), and provide chemical functionality to facilitate cross-linking and other changes in the resist film. These chemical changes can then be leveraged in the development step to selectively remove the exposed or unexposed area of the resist film and to create an etch mask for pattern transfer.

The metal oxide-containing film can be patterned directly (i.e., without the use of a separate photoresist) by EUV exposure in a vacuum ambient providing sub-30 nm patterning resolution, for example as described in U.S. Pat. No. 9,996,004, issued Jun. 12, 2018 and titled EUV PHOTOPATTERNING OF VAPOR-DEPOSITED METAL OXIDE-CONTAINING HARDMASKS, the disclosure of which at least relating to the composition, deposition, and patterning of directly photopatternable metal oxide films to form EUV resist masks is incorporated by reference herein. Generally, the patterning involves exposure of the EUV resist with EUV radiation to form a photo pattern in the resist, followed by development to remove a portion of the resist according to the photo pattern to form the mask.

It should also be understood that the while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate, having exposed hydroxyl groups, is contacted with a hydrocarbyl-substituted tin capping agent to form a hydrocarbyl-terminated SnOx film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology.

Directly photopatternable EUV resists may be composed of or contain metals and/or metal oxides mixed within organic components. The metals/metal oxides are highly promising in that they can enhance the EUV photon adsorption and generate secondary electrons and/or show increased etch selectivity to an underlying film stack and device layers.

When fabricating semiconductor devices, it is important for the fabrication process to be precise and repeatable. Unfortunately, as a semiconductor fabrication reaction chamber processes multiple substrates over time, the processing conditions and chemistries within the reaction chamber change. During deposition and application of a metal-containing resist film on a semiconductor substrate, e.g., dry deposition as described herein, there may be some unintended deposition of metal-containing material on chamber surfaces. After performing several processing operations in a process chamber, the unintended formation of metal-containing material on chamber surfaces may reach a level that makes the metal-containing material more prone to flaking and peeling. In some instances, particles and film impurities originating from the metal-containing material on internal surfaces of the process chamber may fall onto a substrate surface during processing. For example, particles and film impurities may originate from internal chamber walls, ceiling, showerhead, substrate support, lift pins, gas lines, nozzles, etc. Such particles and film impurities that flake or peel from internal surfaces of the process chamber may result in contamination and defect issues in semiconductor substrates. This contamination not only causes contamination in a semiconductor substrate itself, but potentially causes contamination in downstream processing tools such as patterning (scanner) and development tools. In addition, buildup of metal-containing material may shift deposition conditions via outgassing or absorption of precursor material.

Conventionally, removal of unintended deposits on internal surfaces of a process chamber can be performed by manually opening up the process chamber and mechanically scrubbing/wiping the internal surfaces using one or more cleaning agents. In some instances, these methods may involve replacement of parts and can take more than a day to perform chamber maintenance Such methods may be time-consuming, costly, and ineffective.

### Thermal and Plasma Dry Clean of Metal-Containing Material in a Process Chamber

The present disclosure provides for a dry clean of metal-containing material from internal surfaces of a process chamber. The dry clean can be performed using a plasma-only approach, where all or a substantial portion of the metal-containing material formed on internal surfaces of the process chamber are removed by a plasma process. The dry clean can be performed using a hybrid thermal and plasma approach, where some portions of the metal-containing material formed on internal surfaces of the process chamber are removed by a thermal process and other portions are modified by the thermal process, and the other modified portions are removed or substantially removed by a plasma process. In alternative implementations, some portions of the metal-containing material formed on internal surfaces of the process chamber are removed by a plasma process and other portions are modified by the plasma process, and the other modified portions are removed or substantially removed by a thermal process. The thermal process may perform removal and/or modification of metal-containing material by exposure to a halide-containing chemistry without striking plasma. The plasma process may perform removal and/or modification of metal-containing material by exposure to plasma, where the plasma may include a halide-containing plasma, a hydrogen-containing plasma, a hydrocarbon-containing plasma, or combinations thereof. In some embodiments, dry clean of the process chamber may further involve exposing the internal surfaces of the process chamber to plasma configured to remove residual etch gases and organic material from the process chamber. The dry clean of the process chamber may be performed in any process chamber used in deposition, bevel edge and/or backside clean, exposure, bake, development, or etch operation.

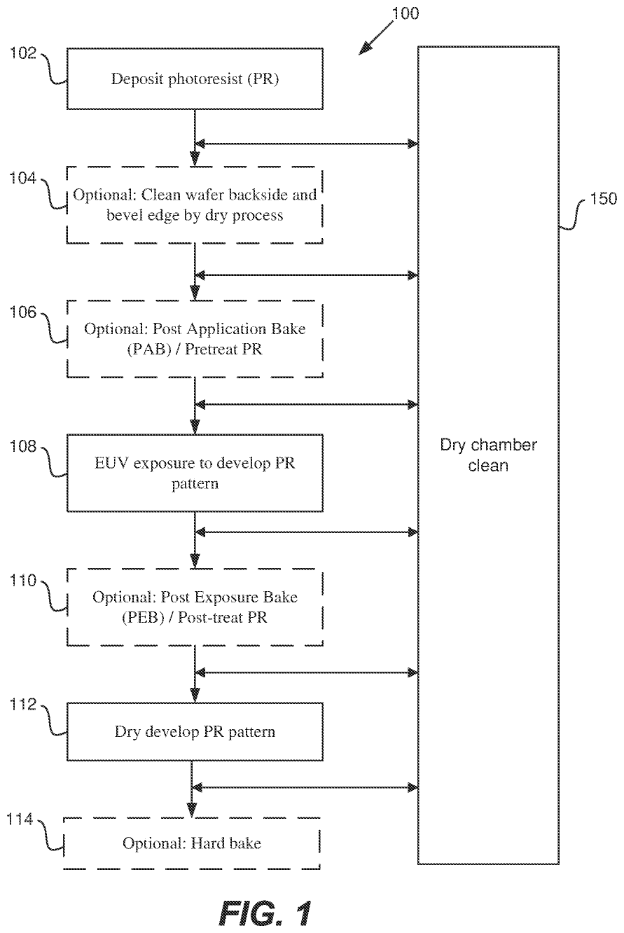

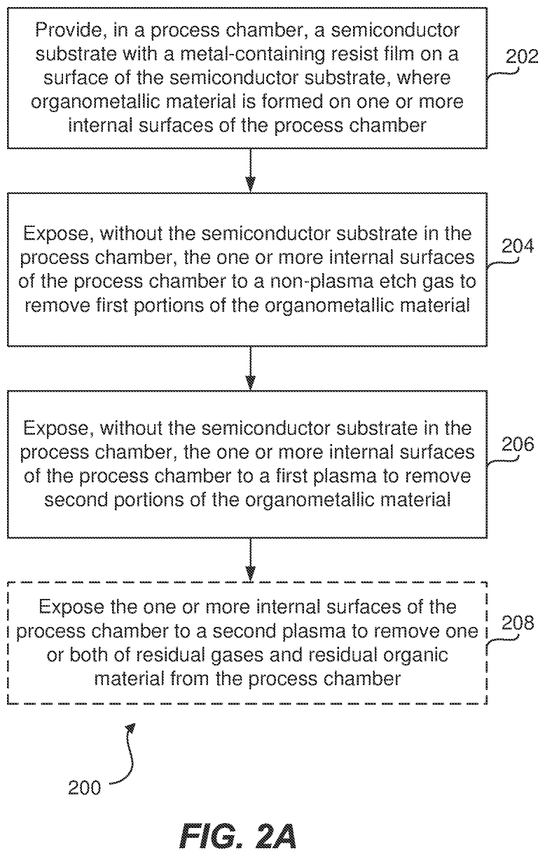

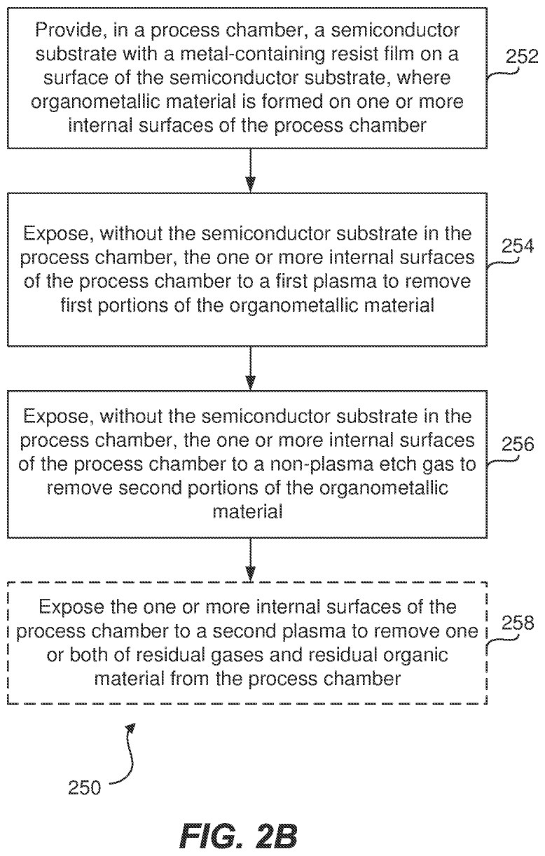

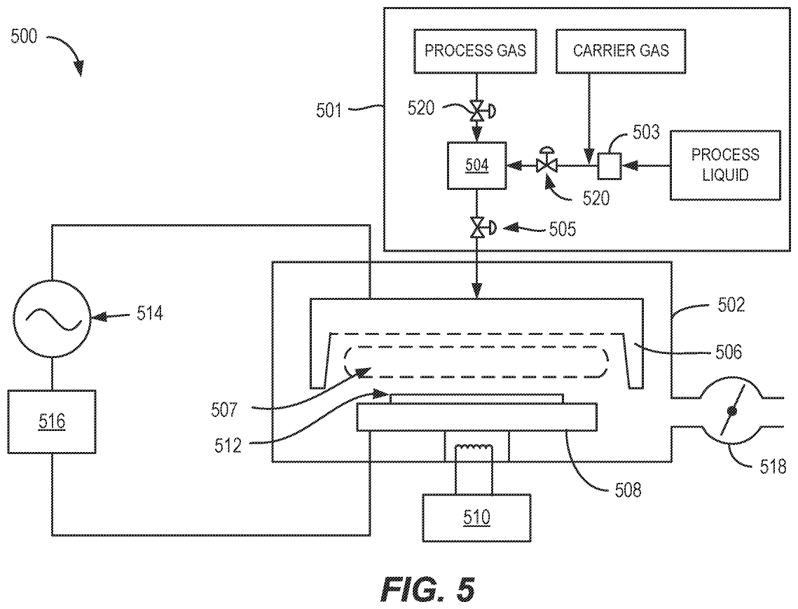

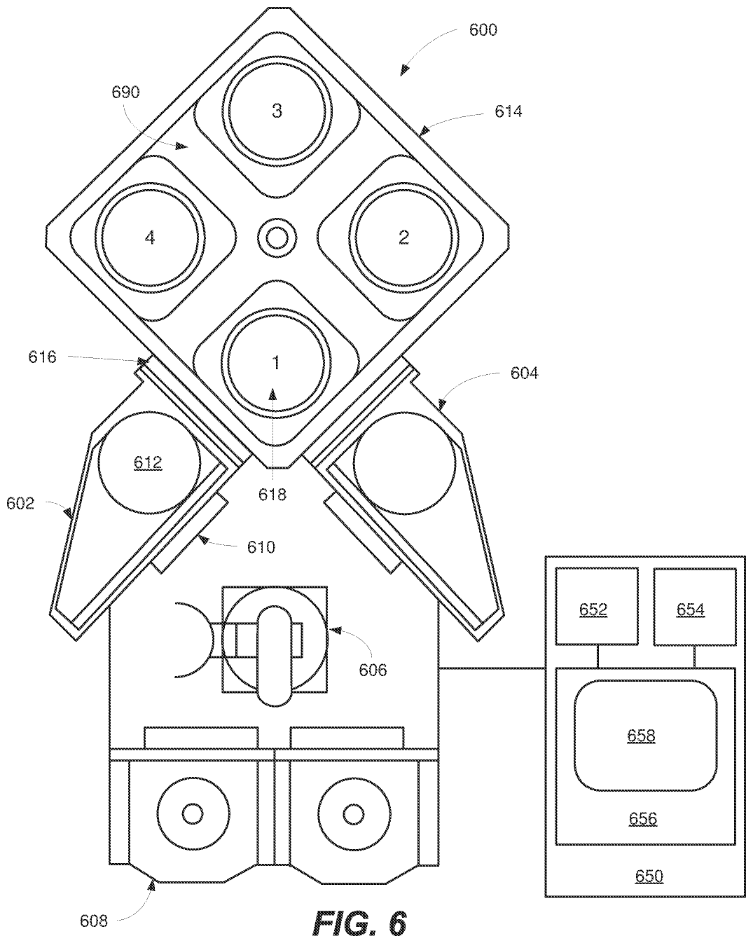

FIG. 1 presents a flow diagram of an example method for depositing and developing a metal-containing photoresist according to some implementations. Specifically, the flow diagram for a process 100 represents dry chamber clean when performing deposition, development, and other photolithographic operations of the metal-containing photoresist. The operations of a process 100 may be performed in different orders and/or with different, fewer, or additional operations. Aspects of the process 100 may be described with reference to FIGS. 2A-2B, FIGS. 3A-3F, and FIGS. 4A-4D. One or more operations of the process 100 may be performed using an apparatus described in any one of FIGS. 5-8. In some embodiments, the operations of the process 100 may be implemented, at least in part, according to software stored in one or more non-transitory computer readable media. In some implementations, dry chamber clean may be performed after deposition, bevel edge and/or backside clean, post application bake, exposure, post exposure bake, or dry development.

At block 102 of the process 100, a layer of photoresist is deposited. This may be either a dry deposition process such as a vapor deposition process or a wet process such as a spin-on deposition process.

The photoresist may be a metal-containing EUV resist. An EUV-sensitive metal or metal oxide-containing film may be deposited on a semiconductor substrate by any suitable technique, including wet (e.g., spin-on) or dry (e.g., CVD) deposition techniques. For example, described processes have been demonstrated for EUV photoresist compositions based on organotin oxides, being applicable to both commercially spin-coatable formulations (e.g., such as are available from Inpria Corp, Corvallis, OR) and formulations applied using dry vacuum deposition techniques, further described below.

Semiconductor substrates may include any material construct suitable for photolithographic processing, particularly for the production of integrated circuits and other semiconducting devices. In some embodiments, semiconductor substrates are silicon wafers. Semiconductor substrates may be silicon wafers upon which features have been created (“underlying features”), having an irregular surface topography. As referred to herein, the “surface” of a substrate is a surface onto which a film of the present disclosure is to be deposited or that is to be exposed to EUV during processing. Underlying features may include regions in which material has been removed (e.g., by etching) or regions in which materials have been added (e.g., by deposition) during processing prior to conducting a method of this disclosure. Such prior processing may include methods of this disclosure or other processing methods in an iterative process by which two or more layers of features are formed on the substrate.

EUV-sensitive thin films may be deposited on the semiconductor substrate, such films being operable as resists for subsequent EUV lithography and processing. Such EUV-sensitive thin films comprise materials which, upon exposure to EUV, undergo changes, such as the loss of bulky pendant substituents bonded to metal atoms in low density M-OH rich materials, allowing their crosslinking to denser M-O-M bonded metal oxide materials. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some implementations, the unexposed film has a more hydrophobic surface than the exposed film under the conditions at which such subsequent processing is performed. For example, the removal of material may be performed by leveraging differences in chemical composition, density and cross-linking of the film. Removal may occur by dry processing as further described below.

The thin films are, in various implementations, organometallic materials, for example organotin materials comprising tin oxide, or other metal oxide materials/moieties. The organometallic compounds may be made in a vapor phase reaction of an organometallic precursor with a counter reactant. In various implementations, the organometallic compounds are formed through mixing specific combinations of organometallic precursors having bulky alkyl groups or fluoroalkyl groups with counter-reactants and polymerizing the mixture in the vapor phase to produce a low-density, EUV-sensitive material that deposits onto the semiconductor substrate.

In various implementations, organometallic precursors comprise at least one alkyl group on each metal atom that can survive the vapor-phase reaction, while other ligands or ions coordinated to the metal atom can be replaced by the counter-reactants. Organometallic precursors include those of the formula:

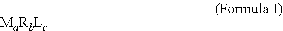

wherein: M is an element with a high patterning radiation-absorption cross-section; R is alkyl, such as CₙH₂ₙ₊₁, preferably wherein n=1-6; L is a ligand, ion or other moiety which is reactive with the counter-reactant; a≥1; b≥1; and c≥1.

In various implementations, M has an atomic absorption cross section equal to or greater than 1×10⁷ cm²/mol. M may be, for example, selected from the group consisting of tin, hafnium, tellurium, bismuth, indium, antimony, iodine, germanium, and combinations thereof. In some implementations, M is tin. R may be fluorinated, e.g., having the formula CₙFₓH₍₂ₙ₊₁₎. In various implementations, R has at least one beta-hydrogen or beta-fluorine. For example, R may be selected from the group consisting of methyl, ethyl, i-propyl, n-propyl, t-butyl, i-butyl, n-butyl, sec-butyl, n-pentyl, i-pentyl, t-pentyl, sec-pentyl, and mixtures thereof. L may be any moiety readily displaced by a counter-reactant to generate an M-OH moiety, such as a moiety selected from the group consisting of amines (such as dialkylamino, monoalkylamino), alkoxy, carboxylates, halogens, and mixtures thereof.

Organometallic precursors may be any of a wide variety of candidate metal-organic precursors. For example, where M is tin, such precursors include t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(dimethylamino) tin, ethyl tris(dimethylamino) tin and analogous alkyl(tris)(t-butoxy) tin compounds such as t-butyl tris(t-butoxy) tin. In some implementations, the organometallic precursors are partially fluorinated.

Counter-reactants have the ability to replace the reactive moieties, ligands or ions (e.g., L in Formula 1, above) so as to link at least two metal atoms via chemical bonding. Counter-reactants can include water, peroxides (e.g., hydrogen peroxide), di- or polyhydroxy alcohols, fluorinated di- or polyhydroxy alcohols, fluorinated glycols, and other sources of hydroxyl moieties. In various implementations, a counter-reactant reacts with the organometallic precursor by forming oxygen bridges between neighboring metal atoms. Other potential counter-reactants include hydrogen sulfide and hydrogen disulfide, which can crosslink metal atoms via sulfur bridges.

The thin films may include optional materials in addition to an organometallic precursor and counter-reactants to modify the chemical or physical properties of the film, such as to modify the sensitivity of the film to EUV or enhancing etch resistance. Such optional materials may be introduced, such as by doping during vapor phase formation prior to deposition on the semiconductor substrate, after deposition of the thin film, or both. In some implementations, a gentle remote H₂ plasma may be introduced so as to replace some Sn-L bonds with Sn—H, which can increase reactivity of the resist under EUV.

In various implementations, the EUV-patternable films are made and deposited on the semiconductor substrate using vapor deposition equipment and processes among those known in the art. In such processes, the polymerized organometallic material is formed in vapor phase or in-situ on the surface of the semiconductor substrate. Suitable processes include, for example, chemical vapor deposition (CVD), atomic layer deposition (ALD), and ALD with a CVD component, such as a discontinuous, ALD-like process in which metal precursors and counter-reactants are separated in either time or space.

In general, methods comprise mixing a vapor stream of an organometallic precursor with a vapor stream of a counter-reactant so as to form a polymerized organometallic material, and depositing the organometallic material onto the surface of the semiconductor substrate. In some implementations, more than one organometallic precursor is included in the vapor stream. In some implementations, more than one counter-reactant is included in the vapor stream. As will be understood by one of ordinary skill in the art, the mixing and depositing aspects of the process may be concurrent, in a substantially continuous process.

In an example continuous CVD process, two or more gas streams, in separate inlet paths, of organometallic precursor and source of counter-reactant are introduced to the deposition chamber of a CVD apparatus, where they mix and react in the gas phase, to form agglomerated polymeric materials (e.g., via metal-oxygen-metal bond formation). The streams may be introduced, for example, using separate injection inlets or a dual-plenum showerhead. The apparatus is configured so that the streams of organometallic precursor and counter-reactant are mixed in the chamber, allowing the organometallic precursor and counter-reactant to react to form a polymerized organometallic material. Without limiting the mechanism, function, or utility of present technology, it is believed that the product from such vapor-phase reaction becomes heavier in molecular weight as metal atoms are crosslinked by counter-reactants, and is then condensed or otherwise deposited onto the semiconductor substrate. In various implementations, the steric hindrance of the bulky alkyl groups prevents the formation of densely packed network and produces smooth, amorphous, low-density films.

In some implementations, the EUV-patternable films are made and deposited on the semiconductor substrate using wet deposition equipment and processes among those known in the art. For example, the organometallic material is formed by spin-coating on the surface of the semiconductor substrate.

The thickness of the EUV-patternable film formed on the surface of the semiconductor substrate may vary according to the surface characteristics, materials used, and processing conditions. In various implementations, the film thickness may range from 0.5 nm to 100 nm, and may be a sufficient thickness to absorb most of the EUV light under the conditions of EUV patterning. The EUV-patternable film may be able to accommodate absorption equal to or greater than 30%, thereby having significantly fewer EUV photons available towards the bottom of the EUV-patternable film. Higher EUV absorption leads to more cross-linking and densification near the top of an EUV-exposed film compared to the bottom of the EUV-exposed film. Though insufficient cross-linking may cause the resist to be more prone to liftoff or collapse in wet development, such as risk is not as present in dry development. An all-dry lithography approach may facilitate more efficient utilization of EUV photons by more opaque resist films. Though efficient utilization of EUV photons may occur with EUV-patternable films having higher overall absorption, it will be understood that in some instances, the EUV-patternable film may be less than about 30%. For comparison, the maximum overall absorption of most other resist films is less than 30% (e.g., 10% or less, or 5% or less) so that the resist material at the bottom of the resist film is sufficiently exposed. In some implementations, the film thickness is from 10 nm to 40 nm or from 10 nm to 20 nm. Without limiting the mechanism, function, or utility of present disclosure, it is believed that, unlike wet, spin-coating processes of the art, the processes of the present disclosure have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

In addition to depositing a metal-containing EUV resist thin film on a semiconductor substrate at block 102 of the process 100, some metal-containing material may form on internal surfaces of the process chamber and downstream parts. The internal surfaces may include chamber walls, floors, and ceilings of the process chamber. Other internal surfaces may include a showerhead, nozzles, ESC/pedestal and substrate support surfaces, and passthrough tunnels or passages that connect the process chamber. The metal-containing material may form as a result of dry deposition processes, such as CVD or ALD processes. A thickness of the metal-containing material may increase over time as a result of additional processing (e.g., deposition) operations being performed in the process chamber. The metal-containing material is prone to flake off, shed particles, or peel from the internal surfaces of the process chamber to cause contamination in downstream processes. The buildup of the metal-containing material may also shift deposition conditions via outgassing or absorption of precursor material.

At block 150 of the process 100, a dry chamber clean is performed after deposition of the metal-containing EUV resist thin film at block 102 of the process 100. This allows for deposition and dry cleaning to be performed in the same process chamber. However, it will be understood that the dry chamber clean may be performed in a different process chamber than the deposition operation in some implementations. In fact, the dry chamber clean may be performed subsequent to a bevel edge and/or backside clean, bake, development, or etch operation, since residue (i.e., metal-containing material formed on internal surfaces of the process chamber) may also form inside chambers where any of these operations are performed, which may or may not be the same as the deposition chamber.

The dry-deposited materials being removed are generally composed of Sn, O, C, and N but the same clean approaches can be extended to films of other metal oxide resists and materials. In addition, this approach can be used for film strip and photoresist rework.

At block 104, an optional cleaning process is performed to clean a backside and/or bevel edge of the semiconductor substrate. The backside and/or bevel edge clean may non-selectively etch EUV resist film to equally remove film with various levels of oxidation or crosslinking on the substrate backside and bevel edge. During application of the EUV-patternable film, either by wet deposition processing or dry deposition processing, there may be some unintended deposition of resist material on the substrate bevel edge and/or backside. The unintended deposition may lead to undesirable particles later moving to a top surface of the semiconductor substrate and becoming particle defects. Moreover, this bevel edge and backside deposition can cause downstream processing problems, including contamination of the patterning (scanner) and development tools. Conventionally, removal of this bevel edge and backside deposition is done by wet cleaning techniques. For spin-coated photoresist material, this process is called edge bead removal (EBR) and is performed by directing a stream of solvent from above and below the bevel edge while the substrate is spinning. The same process can be applied to soluble organotin oxide-based resists deposited by vapor deposition techniques.

The substrate bevel edge and/or backside clean may also be a dry clean process. In some implementations, the dry clean process involves a vapor and/or plasma having one or more of the following gases: HBr, HCl, BCl₃, SOCl₂, Cl₂, BBr₃, H₂, O₂, PCl₃, CH₄, methanol, ammonia, formic acid, NF₃, HF. In some implementations, the dry clean process may use the same chemistries as a dry development process described herein. For example, the bevel edge and/or backside clean may use hydrogen halide development chemistry. For the bevel edge and/or backside clean process, the vapor and/or the plasma has to be limited to a specific region of the substrate to ensure that only the backside and the bevel are removed, without any film degradation on a frontside of the substrate.

Process conditions may be optimized for bevel edge and/or backside clean. In some implementations, higher temperature, higher pressure, and/or higher reactant flow may lead to increased etch rate. Suitable process conditions for a dry bevel edge and backside clean may be: reactant flow of 100-10000 sccm (e.g., 500 sccm HCl, HBr, HI, or H₂ and Cl₂ or Br₂. BCl₃ or H₂, or other halogen-containing compound), temperature of −15° C. to 200° C. (e.g., 80° C.), pressure of 20-1000 mTorr (e.g., 100 mTorr) or pressure of 50-765 Torr (e.g., 760 Torr), plasma power of 0 to 500 W at high frequency (e.g., 13.56 MHz, 2.45 GHz, 40 KHz, 2 MHz), and for a time of about 10 to 100 seconds, dependent on the photoresist film and composition and properties. Bevel and/or backside clean may be accomplished using a Coronus® tool available from Lam Research Corporation, Fremont, CA, though a wider range of process conditions may be used according to the capabilities of the processing reactor.

Bevel edge and/or backside clean may alternatively be extended to a full photoresist removal or photoresist “rework” in which an applied EUV photoresist is removed and the semiconductor substrate prepared for photoresist reapplication, such as when the original photoresist is damaged or otherwise defective Photoresist rework should be accomplished without damaging the underlying semiconductor substrate, so an oxygen-based etch should be avoided. Instead, organic vapor chemistries or variants of halogen-containing chemistries may be used. It will be understood that the photoresist rework operation may be applied at any stage during the process 100. Thus, the photoresist rework operation may be applied after deposition, after bevel edge and/or backside clean, after PAB treatment, after EUV exposure, after PEB treatment, after development, or after hard bake. In some implementations, the photoresist rework may be performed for non-selective removal of exposed and unexposed regions of the photoresist but selective to an underlayer.

In some implementations, the photoresist rework process involves a vapor and/or plasma having one or more of the following gases: HBr, HCl, HI, BCl₃, Cl₂, BBr₃, H₂, PCl₃, CH₄, methanol, ammonia, formic acid, NF₃, HF. In some implementations, the photoresist rework may use the same chemistries as a dry chamber clean process described herein. For example, the photoresist rework may use a hydrogen halide chemistry.

Process conditions may be optimized for the photoresist rework. In some implementations, higher temperature, higher pressure, and/or higher reactant flow may lead to increased etch rate. Suitable process conditions for a photoresist rework may be: reactant flow of 100-5000 sccm (e.g., 500 sccm HCl, HBr, HI, BCl₃ or H₂ and Cl₂ or Br₂), temperature of −20° C. to 140° C. (e.g., 80° C.), pressure of 20-50000 mTorr (e.g., 300 mTorr) or pressure of 50-765 Torr (e.g., 760 Torr), plasma power of 0 to 2000 W (e.g., 500 W) at high frequency (e.g., 13.56 MHz, 2.45 GHz, 40 KHz, 2 MHz), wafer bias of 0 to 200 V_{b} (a higher bias may be used with harder underlying substrate materials) and for a time of about 20 seconds to 30 minutes, sufficient to completely remove the EUV photoresist, dependent on the photoresist film and composition and properties. It should be understood that while these conditions are suitable for some processing reactors, e.g., a Kiyo etch tool available from Lam Research Corporation, Fremont, CA, a wider range of process conditions may be used according to the capabilities of the processing reactor.

At block 150 of the process 100, a dry chamber clean operation may be performed after a bevel edge and/or backside clean at block 104 of the process 100. This allows for bevel edge and/or backside clean and dry chamber clean to be performed in the same process chamber. However, it will be understood that the dry chamber clean may be performed in a different process chamber than the bevel edge and/or backside clean in some implementations.

At block 106 of the process 100, an optional post-application bake (PAB) is performed after deposition of the metal-containing EUV resist film and prior to EUV exposure. The PAB treatment may involve a combination of thermal treatment, chemical exposure, and moisture to increase the EUV sensitivity of the metal-containing EUV resist film, reducing the EUV dose to develop a pattern in the metal-containing EUV resist film. The PAB treatment temperature may be tuned and optimized for increasing the sensitivity of the metal-containing EUV resist film. For example, the treatment temperature may be between about 90° C. and about 200° C. or between about 150° C. and about 190° C. In some implementations, the PAB treatment may be conducted with a pressure between atmospheric and vacuum, and a treatment duration of about 1 to 15 minutes, for example about 2 minutes. In some implementations, the PAB treatment is conducted at a temperature between about 100° C. to 230° C. for about 1 minute to 5 minutes.

At block 150 of the process 100, a dry chamber clean operation may be performed after the PAB treatment at block 106 of the process 100. This allows for bake and dry chamber clean to be performed in the same process chamber. However, it will be understood that the dry chamber clean may be performed in a different process chamber than the PAB treatment in some implementations.

At block 108 of the process 100, the metal-containing EUV resist film is exposed to EUV radiation to develop a pattern. Generally speaking, the EUV exposure causes a change in the chemical composition and cross-linking in the metal-containing EUV resist film, creating a contrast in etch selectivity that can be exploited for subsequent development.

The metal-containing EUV resist film may then be patterned by exposing a region of the film to EUV light, typically under relatively high vacuum. EUV devices and imaging methods among those useful herein include methods known in the art. In particular, as discussed above, exposed areas of the film are created through EUV patterning that have altered physical or chemical properties relative to unexposed areas. For example, in exposed areas, metal-carbon bond cleavage may occur, as through a beta-hydride elimination, leaving behind reactive and accessible metal hydride functionality that can be converted to hydroxide and cross-linked metal oxide moieties via metal-oxygen bridges during a subsequent post-exposure bake (PEB) step. This process can be used to create chemical contrast for development as a negative tone resist. In general, a greater number of beta-H in the alkyl group results in a more sensitive film. This can also be explained as weaker Sn—C bonding with more branching. Following exposure, the metal-containing EUV resist film may be baked, so as to cause additional cross-linking of the metal oxide film. The difference in properties between exposed and unexposed areas may be exploited in subsequent processing, such as to dissolve unexposed areas or to deposit materials on the exposed areas. For example the pattern can be developed using a dry method to form a metal oxide-containing mask.

In particular, in various implementations, the hydrocarbyl-terminated tin oxide present on the surface is converted to hydrogen-terminated tin oxide in the exposed region(s) of an imaging layer, particularly when the exposure is performed in a vacuum using EUV. However, removing exposed imaging layers from vacuum into air, or the controlled introduction of oxygen, ozone, H₂O₂, or water, can result in the oxidation of surface Sn—H into Sn—OH. The difference in properties between exposed and unexposed regions may be exploited in subsequent processing, such as by reacting the irradiated region, the unirradiated region, or both, with one or more reagents to selectively add material to or remove material from the imaging layer.

Without limiting the mechanism, function or utility of present technology, EUV exposure, for example, at doses of from 10 mJ/cm² to 100 mJ/cm² results in the cleavage of Sn—C bonds resulting is loss of the alkyl substituent, alleviating steric hindrance and allowing the low-density film to collapse. In addition, reactive metal-H bond generated in the beta-hydride elimination reactions can react with neighboring active groups such as hydroxyls in the film, leading to further cross-linking and densification, and creating chemical contrast between exposed and unexposed region(s).

Following exposure of the metal-containing EUV resist film to EUV light, a photopatterned metal-containing EUV resist is provided. The photopatterned metal-containing EUV resist includes EUV-exposed and unexposed regions.

At block 150 of the process 100, a dry chamber clean operation may be performed after EUV exposure at block 108 of the process 100. This allows for exposure and dry chamber clean to be performed in the same process chamber. However, it will be understood that the dry chamber clean may be performed in a different process chamber than the EUV exposure in some implementations.

At block 110 of the process 100, an optional post-exposure bake (PEB) is performed to further increase contrast in etch selectivity of the photopatterned metal-containing EUV resist. The photopatterned metal-containing EUV resist can be thermally treated in the presence of various chemical species to facilitate cross-linking of the EUV-exposed regions or simply baked on a hot plate in ambient air, for example between 100° C. and 250° C. for between one and five minutes (e.g., 190° C. for two minutes).

In various implementations, a bake strategy involves careful control of the bake ambient, introduction of reactive gases, and/or careful control of the ramping rate of the bake temperature. Examples of useful reactive gases include e.g., air, H₂O, H₂O₂ vapor, CO₂, CO, O₂, O₃, CH₄, CH₃OH, N₂, H₂, NH₃, N₂O, NO, alcohol, acetyl acetone, formic acid, Ar, He, or their mixtures. The PEB treatment is designed to (1) drive complete evaporation of organic fragments that are generated during EUV exposure and (2) oxidize any Sn—H, Sn—Sn, or Sn radical species generated by EUV exposure into metal hydroxide, and (3) facilitate cross-linking between neighboring Sn—OH groups to form a more densely crosslinked SnO₂-like network. The bake temperature is carefully selected to achieve optimal EUV lithographic performance. Too low a PEB temperature would lead to insufficient cross-linking, and consequently less chemical contrast for development at a given dose. Too high a PEB temperature would also have detrimental impacts, including severe oxidation and film shrinkage in the unexposed region (the region that is removed by development of the patterned film to form the mask in this example), as well as, undesired interdiffusion at the interface between the photopatterned metal-containing EUV resist and an underlayer, both of which can contribute to loss of chemical contrast and an increase in defect density due to insoluble scum. The PEB treatment temperature may be between about 100° C. and about 300° C., between about 170° C. and about 290° C., or between about 200° C. and about 240° C. In some implementations, the PEB treatment may be conducted with a pressure between atmospheric and vacuum, and a treatment duration of about 1 to 15 minutes, for example about 2 minutes. In some implementations, PEB thermal treatment may be repeated to further increase etch selectivity.

At block 150 of the process 100, a dry chamber clean operation may be performed after the PEB treatment at block 110 of the process 100. This allows for bake and dry chamber clean to be performed in the same process chamber. However, it will be understood that the dry chamber clean may be performed in a different process chamber than the PEB treatment in some implementations.

At block 112 of the process 100, the photopatterned metal-containing EUV resist is developed to form a resist mask. In various implementations, the exposed regions are removed (positive tone) or the unexposed regions are removed (negative tone). In some implementations, development may include selective deposition on either the exposed or unexposed regions of the photopatterned metal-containing EUV resist, followed by an etching operation. In some implementations, development may be done with exposure to an etch gas comprising halide-containing chemistry. The development may be done without striking a plasma in some implementations. Or, development may be done with flows of one or more halide-containing etch gases activated in a remote plasma source or activated by exposure to remote UV radiation. The photoresist for development may include an element selected from the group consisting of: tin, hafnium, tellurium, bismuth, indium, antimony, iodine, and germanium. The element may have a high patterning radiation-absorption cross-section. In some implementations, the element may have a high EUV-absorption cross-section. In some implementations, the metal-containing EUV resist may have an overall absorption greater than 30%. In an all-dry lithography process, this provides more efficient utilization of EUV photons, enabling development of thicker and more EUV-opaque resists.

Examples of processes for development involve an organotin oxide-containing EUV-sensitive photoresist thin film (e.g., 10-30 nm thick, such as 20 nm), subjected to a EUV exposure dose and post-exposure bake, and then developed. The photoresist film may be, for example, deposited based on a gas phase reaction of an organotin precursor such as isopropyl(tris)(dimethylamino)tin and water vapor, or may be a spin-on film comprising tin clusters in an organic matrix.

At block 150 of the process 100, a dry chamber clean may be performed after dry development at block 112 of the process 100. This allows for dry development and dry chamber clean to be performed in the same process chamber. However, it will be understood that the dry chamber clean may be performed in a different process chamber than the dry development in some implementations. Moreover, it will be understood that the dry chamber clean may be performed in the same or different process chamber than an etch operation. The etch operation may be applied to etch a substrate underlayer of the semiconductor substrate.

At block 114 of the process 100, the semiconductor substrate optionally undergoes a hard bake. During the hard bake, the semiconductor substrate is subjected to an elevated temperature. For example, the semiconductor substrate may be subjected to an elevated temperature equal to or greater than about 50° C., between about 100° C. and about 300° C., or between about 170° C. and about 290° C. The hard bake may drive out remaining solvents or etch gas from development.

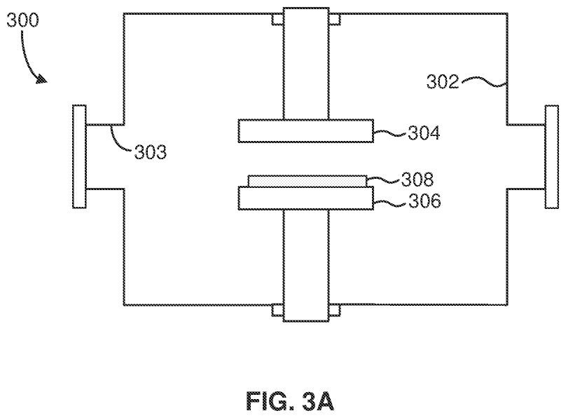

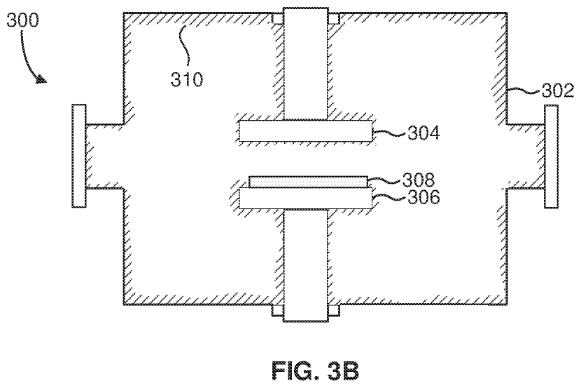

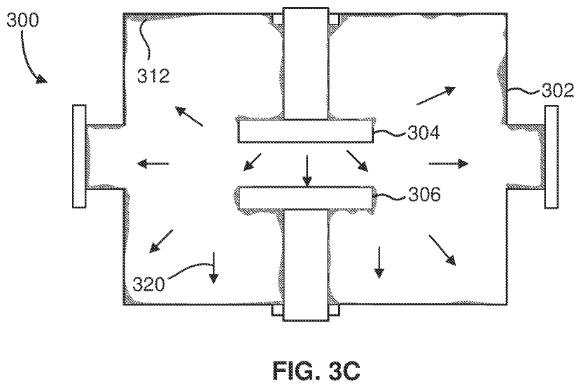

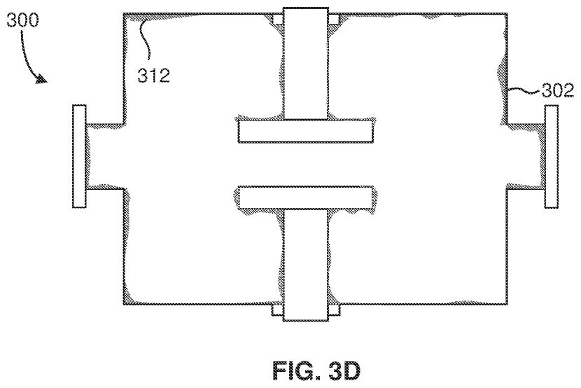

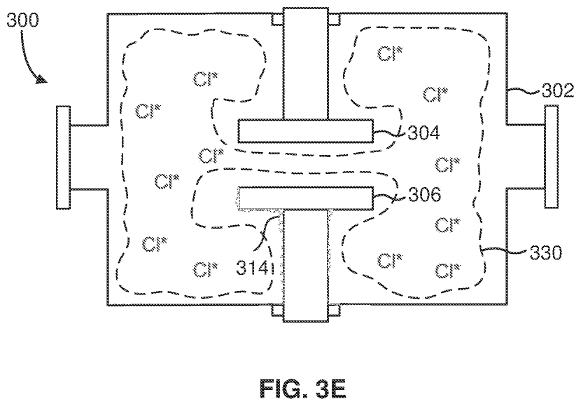

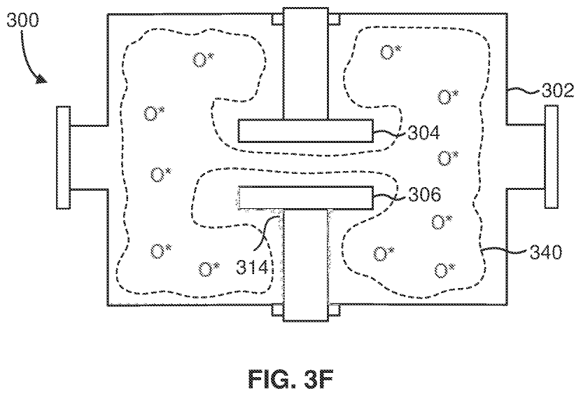

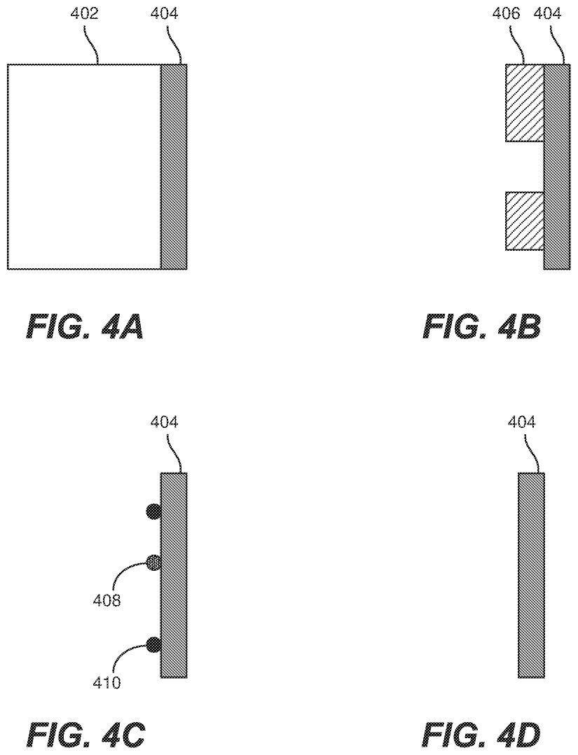

FIG. 2A presents a flow diagram of an example method of performing a dry chamber clean using thermal and plasma processes according to some implementations. The operations of a process 200 may be performed in different orders and/or with different, fewer, or additional operations. Aspects of the process 200 may be described with reference to FIGS. 3A-3F and FIGS. 4A-4D. One or more operations of the process 200 may be performed using an apparatus described in any one of FIGS. 5-8. In some implementations, the operations of the process 200 may be implemented, at least in part, according to software stored in one or more non-transitory computer readable media.

At block 202 of the process 200, a semiconductor substrate with a metal-containing resist film on a surface of a semiconductor substrate is provided in a process chamber. In addition, organometallic material is formed on one or more internal surfaces of the process chamber. The organometallic material formed on the one or more internal surfaces of the process chamber may have the same or similar chemical composition as the metal-containing resist film on the semiconductor substrate.

The metal-containing resist film may be deposited on the surface of the semiconductor substrate in the process chamber or in another chamber (i.e., deposition chamber), where the metal-containing resist film is dry or wet deposited on the semiconductor substrate. In some implementations, the metal-containing resist film is provided as a photopatterned metal-containing resist film after undergoing development. In some implementations, the metal-containing resist film is provided as a positive tone or negative tone resist film having EUV-exposed and EUV-unexposed regions after EUV exposure. In some implementations, the metal-containing resist film is provided as photopatternable metal-containing resist film prior to EUV exposure and development. In some implementations, the metal-containing resist film is metal-containing EUV resist film, where the metal-containing EUV resist film may be an organo-metal oxide or organo-metal-containing film. The organo-metal oxide film may include tin oxide. The composition of metal-containing resist film may be described, for example, in International Patent Application No. PCT/US2019/31618, filed May 9, 2019, incorporated by reference herein in its entirety and for all purposes. Methods include those where polymerized organometallic materials are produced in the vapor phase and deposited on the semiconductor substrate. For example, an element in the metal-containing resist film may be selected from a group consisting of: tin, hafnium, tellurium, bismuth, indium, antimony, iodine, germanium, and combinations thereof.

The metal-containing resist film may be deposited in the process chamber or otherwise undergo processing (e.g., bake, development, rework, etc.) in the process chamber. Processing substrates in the process chamber may cause accumulation of unintended resist material over time. In some embodiments, the process chamber in which the semiconductor substrate is provided may be an exposure chamber. Exposure may result in unintended deposits on chamber surfaces. In some embodiments, the process chamber in which the semiconductor substrate is provided may be a dry deposition chamber. Providing the semiconductor substrate may involve dry depositing the metal-containing resist film on the surface of the semiconductor substrate. Unintended metal-containing material may form on the one or more internal surfaces of the process chamber as the organometallic material. The unintended metal-containing material may form as a result of dry deposition processes such as CVD or ALD processes. In other embodiments, the process chamber in which the semiconductor substrate is provided may be a bevel edge and/or backside clean chamber. Without being limited by any theory, unwanted metal-containing resist film may be removed from certain regions of the semiconductor substrate during bevel edge and/or backside cleaning, but such processing may result in re-deposition of metal-containing material on internal surfaces of the process chamber. In some other embodiments, the process chamber in which the semiconductor substrate is provided may be a PAB treatment chamber or PEB treatment chamber. In such cases, providing the semiconductor substrate may involve baking the metal-containing resist film on the surface of the semiconductor substrate in the process chamber. Unintended metal-containing material may form on the one or more internal surfaces of the process chamber as the organometallic material. By way of an example, baking the metal-containing resist film in the PAB treatment chamber or PEB treatment chamber may result in outgassing of materials that get coated on internal surfaces of the PAB treatment chamber or PEB treatment chamber. In some other embodiments, the process chamber in which the semiconductor substrate is provided may be a development chamber. In such instances, providing the semiconductor substrate may involve dry developing the metal-containing resist film on the surface of the semiconductor substrate. Unintended metal-containing material may form on the one or more internal surfaces of the process chamber as the organometallic material. For instance, dry developing may result in formation of volatile byproducts that get re-deposited as the metal-containing material on the one or more internal surfaces of the process chamber.

As more and more semiconductor substrates are processed in the process chamber, unintended metal-containing material may grow on the internal surfaces. The unintended metal-containing material may form on chamber walls, ceilings, floors, showerhead surfaces, nozzle surfaces, passthrough tunnels and passages, and substrate support surfaces. Periodic cleaning is needed to remove the unintended deposits of the metal-containing material. The cleaning is performed “in-situ,” where the dry chamber clean is performed in the same process chamber where unintended metal-containing material (e.g., organometallic material) formed.

FIG. 3A shows a cross-sectional schematic illustration of a process chamber with a semiconductor substrate supported on a pedestal. A process chamber 300 for processing a semiconductor substrate 308 may include chamber walls 302 enclosing a processing space of the process chamber 300 and a pedestal 306 for supporting the semiconductor substrate 308. The chamber walls 302 may include passages 303 that connect the process chamber 300 to other tools or components, such as a vacuum transport module. In some instances, the process chamber 300 may further include a showerhead 304 or other gas distributor for introducing process gases into the process chamber 300. Internal surfaces of the process chamber 300 may include the chamber walls 302 and other exposed, internal surfaces of chamber components. Other such exposed, internal surfaces of chamber components may include exposed surfaces of a pedestal 306, exposed surfaces of the showerhead 304, and passages 303. In some embodiments, the internal surfaces of the process chamber 300 may include, for example, aluminum oxide-based ceramics, anodized aluminum, plastic, alloy C22, yttria coatings, and stainless steel hardware components (generally downstream). Though internal surfaces of the process chamber 300 are not necessarily resistant to plasma and vapors of halogens such as hydrogen halides, internal surfaces of the process chamber 300 are typically composed of materials that are stable in plasma, vapors of halogens, and water vapor. In some implementations, the chamber walls 302 of the process chamber 300 may include aluminum oxide, anodized aluminum, alloy C22, yttria coatings, and plastic.

A semiconductor substrate 308 may be provided in the process chamber 300. The semiconductor substrate 308 may include a substrate layer (not shown) to be etched, where the substrate layer may include spin-on carbon (SoC), spin-on glass (SOG), amorphous carbon, silicon, silicon oxide, silicon nitride, silicon carbide, or silicon oxynitride. A metal-containing photoresist film (not shown) may be dry or wet deposited on the substrate layer of the semiconductor substrate 308. The metal-containing photoresist film may be photopatterned for etching the substrate layer of the semiconductor substrate 308. In some implementations, the metal-containing photoresist film is a metal-containing EUV photoresist film, where the metal-containing EUV photoresist is an organo-metal oxide or organo-metal containing film. For instance, the metal-containing EUV photoresist film may include at least Sn, O, and C atoms.

FIG. 3B shows a cross-sectional schematic illustration of the process chamber with metal-containing material formed on internal surfaces of the process chamber. Metal-containing material 310 is formed on the chamber walls 302 (including passages 303) of the process chamber 300. The semiconductor substrate 308 may undergo one or more processing operations such as lithographic processing operations in the process chamber 300. In some embodiments, the semiconductor substrate 308 undergoes a deposition operation for deposition of the metal-containing resist film. In some embodiments, the semiconductor substrate 308 undergoes a bevel edge and/or backside clean operation for removal of unwanted metal-containing resist film on the bevel edge and/or backside of the semiconductor substrate 308. In some embodiments, the semiconductor substrate 308 undergoes an exposure operation for producing exposed- and unexposed-regions of the metal-containing resist film. In some embodiments, the semiconductor substrate 308 undergoes a bake operation in a PAB treatment or PEB treatment of the metal-containing resist film. In some embodiments, the semiconductor substrate 308 undergoes a development operation for removal of exposed or unexposed regions of the metal-containing resist film. During processing of the semiconductor substrate 308, unintended growth of the metal-containing material 310 may accumulate on the chamber walls 302 of the process chamber 300 as well as on exposed surfaces of the showerhead 304, pedestal 306, and passages 303. The metal-containing material 310 may be undesirable because it can flake or peel from internal surfaces of the process chamber that can result in contamination, drift, and defect issues in semiconductor substrates.

The metal-containing material 310 may have the same composition as the metal-containing photoresist film on the semiconductor substrate 308. In some implementations, the metal-containing material is an organometallic material or organo-metal oxide material. For example, the metal-containing material may include at least Sn, O, and C atoms, or the metal-containing material may include at least Sn, O, C, and N atoms.

FIG. 4A shows a cross-sectional schematic illustration of an organometallic material 402 formed on chamber walls 404 of a process chamber. The organometallic material 402 may include particles or clusters of metal oxide. In some embodiments, the organometallic material 402 is formed by a vapor deposition method such as CVD or ALD. Over time, the organometallic material 402 may accumulate in thickness on the chamber walls 404 of the process chamber. The organometallic material 402 may be an organotin oxide.

Returning to FIG. 2, at block 204 of the process 200, the one or more internal surfaces of the process chamber are exposed to a non-plasma etch gas without the semiconductor substrate in the process chamber to remove first portions of the organometallic material. Some of the other portions may be converted or otherwise modified by exposure to the non-plasma etch gas. Modified portions of the organometallic material may constitute nonvolatile etch byproducts of unremoved portions of the organometallic material. The etch gas may include a halide-containing gas. As used herein, a halide refers to an anion of F, Cl, Br, or I In some embodiments, the halide-containing gas may include a hydrogen halide such as hydrogen fluoride (HF), hydrogen chloride (HCl), hydrogen bromide (HBr), hydrogen iodide (HI), or combinations thereof. The etch gas may include HBr or HCl. In some embodiments, the halide-containing gas may include hydrogen and a halogen gas such as fluorine (F₂), chlorine (Cl₂), bromine (Br₂), and iodine (I₂). In some embodiments, the halide-containing gas may include boron trichloride (BCl₃), boron tribromide (BBr₃), or mixtures thereof. In some other embodiments, the halide-containing gas includes an organic halide, an acyl halide, a carbonyl halide, a thionyl halide, or mixtures thereof. In some cases, the etch gas includes a hydrogen halide, boron trichloride, boron tribromide, or mixtures thereof. In some embodiments, the etch gas is flowed with or without inert/carrier gas such as He, Ne, Ar, Xe, or N₂.

Exposure to the etch gas to remove or modify the organometallic material may be done without plasma. The etch gas may remove the first portions of the organometallic material without striking a plasma. Furthermore, the etch gas may convert or modify other portions of the organometallic material without striking a plasma. Exposure to the non-plasma etch gas may proceed by heating the one or more internal surfaces of the process chamber to an elevated temperature. One or more heaters may be thermally coupled to the one or more surfaces of the process chamber to heat the one or more surfaces to an elevated temperature. In some embodiments, the elevated temperature may be between about −15° C. and about 200° C., between about −15° C. and about 140° C., or between about 0° C. and about 120° C. Higher temperatures may promote volatility of etch byproducts. By applying a plasma-free thermal approach, productivity can be significantly improved. However, as discussed below, the thermal process may be followed by exposure to plasma to further remove organometallic material.

By heating the process chamber to an elevated temperature, the non-plasma etch gas removes the first portions of the organometallic material and optionally modifies other portions of the organometallic material. In some cases, the first portions of the organometallic material removed by the non-plasma etch gas may represent a bulk or a substantial fraction of the organometallic material. In some implementations, “a substantial fraction” of the organometallic material that is removed constitutes at least 60% by volume, at least 70% by volume, at least 80% by volume, or at least 90% by volume of the organometallic material formed on the one or more internal surfaces of the process chamber. By way of an example, if a thickness of the organometallic material is about 5 nm, then the non-plasma etch gas may remove at least 3.75 nm, at least 4 nm, at least 4.25 nm, at least 4.5 nm, or at least 4.75 nm of the organometallic material. In some other cases, however, the first portions of the organometallic material removed by the non-plasma etch gas may represent less than a bulk of the organometallic material. The non-plasma etch gas may convert or otherwise modify a bulk or a substantial fraction of the organometallic material. Converted or modified organometallic material may be more easily removable by plasma as discussed below.

Prior to introducing the non-plasma etch gas, the process chamber may be prepared with desired conditions for dry chamber cleaning. Preparation of the process chamber may achieve certain pressure conditions, levels of loose particles or film impurities, moisture levels, temperature conditions, or protection of surfaces or components (e.g., pedestal) in the process chamber from the etch gas.

In some embodiments, preparing the process chamber may include removing the semiconductor substrate from the process chamber. That way, the process chamber may be free of the semiconductor substrate or any other processing substrate during dry chamber cleaning. Thus, the semiconductor substrate having the metal-containing resist film may be transferred out of the process chamber prior to dry chamber cleaning. In some embodiments, preparing the process chamber may include providing a dummy substrate on a substrate support in the process chamber. The dummy substrate may be provided on the substrate support to protect the substrate support (e.g., electrostatic chuck) from exposure to the non-plasma etch gas during dry chamber cleaning. The dummy substrate may also be provided on the substrate support to protect the substrate support from exposure to plasma during dry chamber cleaning. Alternatively, protection of the substrate support may occur by providing a protective cover over the substrate support during dry chamber cleaning.

In some embodiments, preparing the process chamber may include purging and/or pumping the process chamber to remove unwanted particles in the process chamber. A vacuum line or purge line may be coupled to the process chamber. The vacuum line may include a vacuum pump system, which can include a one or two stage mechanical dry pump and/or turbomolecular pump. A purge gas may be flowed into the process chamber to facilitate removal of unwanted particles in the process chamber. Such unwanted particles may include particles or flakes from the organometallic material and its byproducts. A vacuum pump system may reduce a chamber pressure and/or remove unwanted particles from the process chamber. The vacuum pump system may be configured to produce a vacuum pressure that is in the relatively low range (e.g., between about 6 Torr and atmosphere) or in the relatively high range (e.g., between about 1 mTorr and about 6 Torr). In some embodiments, preparing the process chamber may include a combination of pumping and purging operations.

A purge of metal organic precursor may be useful to avoid undesired byproducts and ensure sufficient removal of the metal organic CVD precursor before dry chamber cleaning. Sufficient pump/purging and/or water dosing may be performed before dry chamber clean to encourage complete reaction. In some embodiments, chamber walls and other components may be heated to release unreacted precursor.

In some embodiments, preparing the process chamber may include increasing a temperature of one or more internal surfaces in the process chamber. Preheating internal surfaces of the process chamber may release unreacted precursor. Preheating internal surfaces may also release reaction byproducts. Unreacted precursor and byproducts can change the material structure of the organometallic material on internal surfaces, which can impact both thermal and plasma processes of the dry chamber clean. Preheating internal surfaces may additionally facilitate removal of moisture in the process chamber. Without being limited by any theory, the presence of water vapor slows down the reaction between the etch gas and the organometallic material for removal/conversion of the organometallic material. In addition, the increased temperature in the process chamber promotes a higher etch rate for removal of the organometallic material. One or more heaters thermally coupled to the one or more internal surfaces of the process chamber heat the one or more internal surfaces to an elevated temperature, such as a temperature between about −20° C. and about 200° C., between about −15° C. and about 180° C., or between about 0° C. and about 140° C.

The non-plasma etch gas may be introduced through a showerhead or separate chamber inlet coupled to the process chamber. The non-plasma etch gas may flow into the process chamber to react with the organometallic material to form volatile products. In some implementations, the non-plasma etch gas may react with the organometallic material to form a volatile product at a temperature less than about 200° C. Without being limited by any theory, the organometallic material may include an organo-metal oxide material that has a tetrahedrally coordinated structure, and an etch gas with a halide-based chemistry (e.g., HBr or HCl) may protonate an oxygen lone pair to form a volatile byproduct such as R—Sn—Br. Water is a byproduct as well. The speed of the reaction may be increased by removal of water and increasing a temperature of the process chamber. After volatile products are formed, the process chamber may be pumped and purged to remove the volatile products. Additionally, the process chamber may be pumped and purged to remove residual etch gas.

The dry chamber clean may be optimized for low etch selectivity or high etch rate of organometallic material deposited in the process chamber. That way, unwanted material may be quickly and efficiently removed. Low etch selectivity may be achieved for non-selective removal of photoresist material and metal oxide materials (e.g., tin oxide). Low etch selectivity may be achieved for non-selective removal of exposed EUV resist material and unexposed EUV resist material. In some embodiments, higher temperatures and/or higher pressures may result in lower etch selectivity of the etch gas. During exposure to the etch gas, the organometallic material on the one or more internal surfaces may be subjected to an elevated temperature. The elevated temperature may be between about −20° C. and about 200° C., between about −15° C. and about 180° C., or between about 0° C. and about 140° C. During exposure to the etch gas, the pressure in the process chamber may be relatively high. In some embodiments, a chamber pressure is between about 0.01 Torr and atmosphere, between about 0.1 Torr and 100 Torr, or between about 0.1 Torr and about 6 Torr. In some embodiments, the chamber pressure is cycled between high and low pressures during exposure to the etch gas. Etch gas flow rate may also be tuned to control etch selectivity. In some embodiments, an etch gas flow rate is between about 50 sccm and about 10000 sccm, between about 100 sccm and about 10000 sccm, or between about 100 sccm and about 5000 sccm.

The non-plasma etch gas generally serves to remove organometallic material from interior chamber surfaces, where the etch rate may be modulated by adjusting a temperature of the one or more internal surfaces of the process chamber. The organometallic material can be removed with an etch rate of greater than 10 nm/s. Higher temperatures and/or pressures may increase the etch rate. The resist material can be removed using vapors at various temperatures (e.g., HCl or HBr at a temperature greater than −20° C.).

Due to the ability to remove portions of as-deposited films (non-exposed or non-crosslinked) thermally, without the need for use of plasma, the approach described herein can also clean the downstream and upstream components of the tool, beyond the process chamber (e.g., the exhaust lines going from the process chamber to the vacuum pump). More generally, this dry chamber clean method can be used to clean other parts and components contaminated having a similar composition of a metal that has volatile products with —Cl, —Br, —F, —H, —CH₄, and an oxide and/or R groups.

In some embodiments, coatings that are compatible with halogen cleaning chemistry may be used on the chamber walls and other components exposed to the dry chamber clean, such as PTFE, anodized aluminum, alloy C22, yttrium oxide (Y₂O₃), or organic polymer coatings. In some embodiments, the process chamber may include chamber parts temperature control coupled to the one or more internal surfaces (e.g., chamber walls) to control temperature. In some embodiments, the process chamber may include gas inlets other than the showerhead for delivery of the etch gas. The gas inlets may be positioned in regions of the process chamber with a higher concentration of the organometallic material. Or, the gas inlets may be positioned in regions of the process chamber where etch gas is less likely to reach through delivery via a showerhead. In some embodiments, the gas inlets may be positioned below the substrate support, positioned in the walls of the process chamber, and/or positioned close to an exhaust of the process chamber. Multiple gas inlets may be used for delivery of the etch gas into the process chamber. This can ensure dry clean of the entire process chamber.

For preventing corrosion of chamber components, the etch gas may be separated from the deposition gases/precursors. In various embodiments, the etch gas is delivered into the process chamber through one or more gas inlets separate from the showerhead, and deposition gases may be delivered into the process chamber through the showerhead. In some embodiments, the showerhead may supply separate gases by keeping the gases largely segregated within the showerhead. The showerhead may include multiple plenum volumes. Multiple exhaust lines may be used to ensure separation of gases downstream from the process chamber. A switch may be operably coupled to the multiple exhaust lines so as to permit separation of etch gas chemistry from deposition gases/precursors. For example, hydrogen halide chemistry may be separated from organotin precursors and water vapor. Halides may be exhausted through a first exhaust line during a pumping/purging operation, and deposition precursors and water vapor may be exhausted through a second exhaust line during a pumping/purging operation.

To protect the showerhead, a pressure differential may be used to prevent the etch gas from entering the showerhead (e.g., backflow). In some embodiments, the etch gas may clean internal surfaces of the showerhead by flowing the etch gas through the showerhead. However, residual halides or moisture may be retained inside channels of the showerhead. In some embodiments, the showerhead may be made out of a transparent material and heated with a suitable light source. For example, an irradiation source tuned to the appropriate wavelength (e.g., IR or blue wavelength) can directly heat the residual halides and/or moisture to remove the residual halides and/or moisture. Alternatively, the residual halides and/or moisture may be removed by gas purging.

In some embodiments, periodic dry chamber cleaning may occur upon detection. A detection source may trigger chamber clean and/or endpoint of clean. The detection source may be a sensor installed in the process chamber, such as a color-based sensor, intensity-based sensor, vision-based camera/sensor, or combination thereof. The sensor may trigger dry chamber clean by monitoring particle count or uniformity, wafer count, or thickness count. Alternatively, the sensor may trigger dry chamber clean by an in-situ measurement device for chamber wall deposition. For example, the sensor may detect the presence of photoresist material using infrared (IR) measurements. After a certain amount of photoresist material is formed or a threshold particle, uniformity, wafer, or thickness count is reached, the dry chamber clean may be triggered. In some embodiments, the sensor may be installed downstream in a foreline. Such a sensor may detect what gases/byproducts are being exhausted. When volatile byproducts are no longer detected in the foreline, the dry chamber clean may be terminated.

FIG. 3C shows a cross-sectional schematic illustration of the process chamber during dry chamber cleaning with a non-plasma etch gas. The semiconductor substrate 308 of FIGS. 3A and 3B is transferred out or otherwise removed from the process chamber 300. An etch gas 320 is flowed into the process chamber 300 to remove portions of the metal-containing material 310 from the internal surfaces of the process chamber 300. Thus, the etch gas 320 may remove portions of the metal-containing material 310 from the chamber walls 302 including the passages 303, and exposed surfaces of the showerhead 304 and pedestal 306.

The etch gas 320 may include a halide-containing gas. In some implementations, the etch gas 320 includes HF, HCl, HBr, HI, BCl₃, BBr₃, or mixtures thereof. For example, the etch gas includes HBr. The etch gas 320 may remove portions of the metal-containing material 310 without striking a plasma. Accordingly, some portions of the metal-containing material 310 are removed in a non-plasma thermal process. Internal surfaces of the process chamber 300 may be heated to a temperature between about −20° C. and about 200° C., between about −15° C. and about 180° C., or between about 0° C. and about 140° C. to drive removal of the metal-containing material 310. However, some of the unremoved portions of the metal-containing material 310 may be left behind as residue 312 on internal surfaces of the process chamber 300, including the chamber walls 302, the passages 303, and exposed surfaces of the showerhead 304 and pedestal 306. The residue 312 may include nonvolatile byproducts that form as a result of modification/conversion of the metal-containing material 310 with the etch gas 320. The residue 312 may constitute such “decomposed” metal-containing material 310 that may be more easily removable by subsequent plasma exposure, but is not readily removable by continued exposure to the etch gas 320 in the non-plasma thermal process. In some cases, the nonvolatile byproducts include nonvolatile tin halides (e.g., Sn(II)-Br). The residue 312 may also include re-deposited metal-containing materials.

FIG. 4B shows a cross-sectional schematic illustration of the chamber walls 404 after an etch gas removes portions of the organometallic material 402 from the chamber walls 404 and converts other portions of the organometallic material 402. The etch gas may be a hydrogen halide such as HBr. The chamber walls 404 may be heated to an elevated temperature to promote low etch selectivity. The process chamber may be increased to a high pressure to promote low etch selectivity. Removal and conversion of organometallic material 402 may occur without using plasma. Thus, portions of the organometallic material 402 are removed in a plasma-free thermal process, and unremoved portions of the organometallic material 402 are converted/modified to form residue 406 on the chamber walls 404. The reaction between the etch gas and the organometallic material 402 may produce a volatile etch byproduct as well as a nonvolatile etch byproduct. The residue 406 may include the nonvolatile etch byproduct. In some cases, the volatile etch byproduct may re-deposit on the chamber walls 404, where the residue 406 may potentially include re-deposited etch byproduct along with the nonvolatile etch byproduct.

Returning to FIG. 2, at block 206 of the process 200, the one or more internal surfaces of the process chamber are exposed to a first plasma to remove second portions of the organometallic material without the semiconductor substrate in the process chamber. Following a thermal process that removes the first portions of the organometallic material and converts some other portions of the organometallic material, a plasma process may follow that removes or substantially removes the some other portions of the organometallic material that were converted. The second portions may constitute the converted organometallic material. As used herein, “substantial removal” of the converted organometallic material may refer to removal of at least 80% by volume or even at least 90% by volume of the converted organometallic material. The first plasma may be configured to form volatile products with the second portions of the organometallic material. In some embodiments, the first plasma may include a halide-containing plasma, hydrogen-containing plasma, hydrocarbon-containing plasma, inert gas-containing plasma, or mixtures thereof.

Plasma-activated species of the first plasma may react with the second portions of the organometallic material to form volatile products. A first process gas, which may be different than the etch gas, may be flowed to the process chamber or to a remote plasma source for igniting the first plasma. The first process gas may include a halide-containing chemistry, hydrogen-containing chemistry, hydrocarbon-containing chemistry, inert gas-containing chemistry, or combinations thereof. In some embodiments, the first process gas for generating the first plasma may include Cl₂, HCl, BCl₃, trichloromethane (CHCl₃), dichloromethane (CH₂Cl₂), tetrachloromethane (CCl₄), HBr, HF, tetrafluoromethane (CF₄), nitrogen trifluoride (NF₃), trifluoromethane (CHF₃), difluoromethane (CH₂F₂), fluoromethane (CH₃F), methane (CH₄), hydrogen (H₂), or mixtures thereof. As such, the first plasma may be a Cl₂ plasma, HCl plasma, BCl₃ plasma, CHCl₃ plasma, CH₂Cl₂ plasma, CCl₄ plasma, HBr plasma, HF plasma, CF₄ plasma, NF₃ plasma, CHF₃ plasma, CH₂F₂ plasma, CH₃F plasma, CH₄ plasma, H₂ plasma, or mixtures thereof. In some embodiments, the first process gas for generating the first plasma may include argon (Ar). Accordingly, the first plasma may include an Ar plasma.

In some embodiments, the first plasma is generated directly in the process chamber. The first process gas may be flowed into the process chamber and distributed throughout the process chamber. RF power may be applied to the process chamber to generate the first plasma comprising plasma-activated species (e.g., radicals/ions) of the first process gas. The first plasma may be generated by inductively-coupled plasma (ICP) generation, transformer-coupled plasma (TCP) generation, capacitively-coupled plasma (CCP) generation, or other methods known in the art. For example, the first plasma may be generated by CCP generation in the process chamber. The first plasma may be controlled to be preferentially directed towards the one or more internal surfaces of the process chamber. Preferentially directing the first plasma in such a manner allows internal surfaces such as chamber walls, ceilings, floors, passthrough tunnels or passages, exposed surfaces of a showerhead, exposed surfaces of a pedestal, and other chamber components to be exposed to the first plasma.

In some embodiments, the first plasma is generated in a remote plasma source fluidly coupled to the process chamber. The first process gas may be flowed into the remote plasma source where RF power is applied to the remote plasma source to generate plasma-activated species (e.g., radicals/ions) of the first process gas. The first plasma may be generated using ICP, TCP, CCP, or other plasma technique known in the art. The first plasma may be delivered from the remote plasma source into the process chamber so that the plasma-activated species are distributed towards the one or more internal surfaces of the process chamber. In some embodiments, the first plasma is delivered from the remote plasma source into the process chamber through a showerhead. Additionally or alternatively, the first plasma is delivered from the remote plasma source into the process chamber through a distributor that preferentially directs the first plasma to the one or more internal surfaces of the process chamber.

Process conditions for applying the first plasma may be controlled to remove the second portions of the organometallic material. In some implementations, the etch gas is composed of a first halide-containing chemistry and the first process gas for the first plasma is composed of a second halide-containing chemistry that may or may not be different than the first halide-containing chemistry. In one example, the etch gas may include HBr and the first process gas for the first plasma may include Cl₂, BCl₃, or a mixture of Cl₂ and BCl₃. In another example, the etch gas may include HBr and the first process gas for the first plasma may include HBr, Cl₂, H₂, Ar, CH₄, a mixture of CH₄ and H₂, a mixture of CH₄ and Ar, a mixture of Ar and Cl₂, a mixture of CH₄ and Cl₂, a mixture of HBr and Ar, or a mixture of CH₄, Cl₂, and Ar. In some implementations, first process gas flow may be between about 50 sccm and about 10000 sccm or between about 100 sccm and about 5000 sccm. In some implementations, a temperature may be between about −60° C. and about 120° C., between about −20° C. and about 100° C., between about −60° C. and about 60° C., or between about 20° C. and about 100° C. In some implementations, chamber pressure may be between about 1 mTorr and about 20 Torr, between about 5 mTorr and about 760 Torr, or between about 5 mTorr and about 100 mTorr. In some implementations, plasma power may be between about 50 W and about 6000 W, between about 100 W and about 3000 W, or between about 100 W and about 800 W. In some implementations, the wafer bias is between about 0 V and about 500 V, between about 10 V and about 300 V, or between about 20 V and about 200 V. The plasma may be generated using a high RF frequency. In some implementations, the RF frequency is 13.56 MHz, 400 kHz, 2 MHz, 2.45 GHz, or 40 MHz. In some implementations, the duration of exposure to the first plasma is between about 5 seconds and about 3000 seconds, between about 10 seconds and about 2000 seconds, or between about 30 seconds and about 1200 seconds.

The first plasma may be configured to remove any re-deposited and decomposed organometallic material remaining in the process chamber. Without being limited by any theory, the etch gas may form volatile byproducts with the organometallic material at block 204 that may be subsequently re-deposited on the one or more internal surfaces of the process chamber. For instance, an etch gas comprising HBr may react with an organometallic material comprising SnOₓ to form volatile R—Sn—Br. Additionally or alternatively, the etch gas may react with the organometallic material to form nonvolatile byproducts/compounds. For instance, an etch gas comprising HBr may react with a photoresist material comprising SnOₓR_{y} to form nonvolatile salts comprising Sn(II)-Br. The second portions of the organometallic material may be composed of such nonvolatile salts or byproducts. The first plasma may be configured with a suitable chemistry and reactivity to react with the second portions of the organometallic material to form volatile byproduct(s).

The process chamber is free of the semiconductor substrate during plasma exposure. In some embodiments, the process chamber may include a dummy substrate on a substrate support in the process chamber. The dummy substrate may be provided on the substrate support to protect the substrate support (e.g., electrostatic chuck) from exposure to plasma during dry chamber cleaning. Alternatively, protection of the substrate support may occur by providing a protective cover over the substrate support during dry chamber cleaning.

FIG. 3D shows a cross-sectional schematic illustration of the process chamber after dry chamber cleaning with a non-plasma etch gas. As discussed above, exposure to the etch gas 320 in FIG. 3C may remove portions of the metal-containing material 310 but leave a residue 312 of the metal-containing material. The residue 312 may be formed on the chamber walls 302 and passages 303 as well as on exposed surfaces of the showerhead 304 and pedestal 306. The etch gas 320 may react with some portions of the metal-containing material 310 to form volatile byproducts, but the etch gas 320 may also react with some other portions of the metal-containing material 310 to form nonvolatile byproducts/compounds. The nonvolatile byproducts formed from the reaction between the etch gas 320 and the metal-containing material 310 may form the residue 312. In some cases, some of the volatile byproducts from the etch gas 320 may re-deposit on the internal surfaces of the process chamber 300, which can form at least part of the residue 312. For instance, where the etch gas 320 comprises HBr and the metal-containing material 310 comprises SnOₓR_{y}, the etch gas 320 may react with some of the metal-containing material 310 to generate nonvolatile salts of Sn(II)-Br. Consequently, continued exposure to HBr in a thermal process may not be sufficient to remove such nonvolatile salts from the internal surfaces of the process chamber 300. The residue 312 may include loose particles that may easily flake or peel off from the internal surfaces of the process chamber 300, where the residue 312 can potentially contaminate wafers and/or downstream processing tools.

FIG. 3E shows a cross-sectional schematic illustration of the process chamber during dry chamber cleaning with a first plasma. The internal surfaces of the process chamber 300 may be exposed to a first plasma 330 to remove the residue 312. Following a thermal process using the etch gas 320 to remove portions of the metal-containing material 310, dry chamber cleaning may proceed with a plasma process using the first plasma 330 to remove the residue 312. The residue 312 may constitute converted or modified portions of the organometallic material 310, where the residue 312 may be reactive with the first plasma 330 to form volatile etch byproducts but not necessarily reactive with the etch gas 320 to form volatile etch byproducts. Exposure to the first plasma 330 may occur without the semiconductor substrate 308 in the process chamber 300.

The first plasma 330 may include radicals and/or ions of the halide-containing gas, a hydrogen-containing gas, hydrocarbon-containing gas, or mixtures thereof. In some implementations, the first plasma 330 includes plasma-activated species of HBr, Cl₂, HCl, BCl₃, CHCl₃, CH₂Cl₂, CCl₄, HBr, HF, CF₄, NF₃, CHF₃, CH₂F₂, CH₃F, CH₄, H₂, Ar, or mixtures thereof. For example, the first plasma 330 includes plasma-activated species of Cl₂, where such plasma-activated species may include chlorine radicals (Cl*). The plasma-activated species of the halide-containing gas, the hydrogen-containing gas, and/or the hydrocarbon-containing gas may provide reactive species for etching the residue 312.

In some embodiments, the first plasma 330 is generated directly in the process chamber 300. The first plasma 330 may be generated using ICP-, TCP-, CCP-, or other suitable plasma generation technique. For instance, the first plasma 330 may be generated in-situ in the process chamber 300 by CCP generation. In such cases, one or both of the showerhead 304 and pedestal 306 may include electrodes, where one or both of the electrodes may be powered to generate the first plasma 330.

In some embodiments, the first plasma 330 is generated in a remote plasma source (not shown) that is separate from the process chamber 300 but fluidly coupled to the process chamber 300. The first plasma 330 may be generated using ICP-, TCP-, CCP-, or other suitable plasma generation technique. In some implementations, the remote plasma source may be located upstream of the process chamber 300 and radicals of halide-containing gas, hydrogen-containing gas, hydrocarbon-containing gas, and/or inert gas may be distributed through the showerhead 304 into the process chamber 300.

All or substantially all of the residue 312 is removed from the internal surfaces of the process chamber 300 after exposure to the first plasma 330. However, it is possible that some residual contaminants 314 may remain in the process chamber 300 even after exposure to the first plasma 330. The residual contaminants 314 may be located in areas of the process chamber 300 that are difficult for the first plasma 330 to reach. Thus, the residual contaminants 314 may include unremoved portions of the residue 312. Additionally or alternatively, the residual contaminants 314 may include residual organic material such as carbon and/or residual etch gas such as residual halide(s).

FIG. 4C shows a cross-sectional schematic illustration of the chamber walls 404 after plasma exposure removes the residue 406 from the chamber walls 404. A primary plasma may be configured to form volatile byproducts with the residue 406. The etch gas in a non-plasma thermal process may be unable to remove the residue 406, but the primary plasma may have a suitable chemistry and reactivity to remove the residue 406. In some cases, the primary plasma may include a halide-containing gas such as chlorine, a hydrocarbon-containing gas such as methane, a hydrogen-containing gas such as hydrogen, an inert gas such as argon, or mixtures thereof. After portions of the organometallic material 402 are removed from the chamber walls 404 by a thermal process, unremoved portions of the organometallic material 402 in the form of the residue 406 may be removed by a plasma process. In some embodiments, the primary plasma is a direct plasma generated in the process chamber. In some embodiments, the primary plasma is a remote plasma generated in a remote plasma source fluidly coupled to the process chamber. After removal of the residue 406, residual etch gas 408 and residual organic material 410 may remain adjacent to or on the chamber walls 404. Other particles or contaminants may remain adjacent to or on the chamber walls 404.

Returning to FIG. 2, at block 208 of the process 200, the one or more internal surfaces of the process chamber are optionally exposed to a second plasma to remove one or both of residual gases and residual organic material from the process chamber. In some embodiments, the second plasma may additionally remove residual salts and other contaminants from the process chamber. Following exposure to the non-plasma etch gas and first plasma to remove the first and second portions of the organometallic material, some residual impurities or contaminants may still remain in the process chamber. These residual impurities or contaminants may include residual carbon and/or residual etch gas (e.g., unreacted halides/halogens). In some instances, the residual etch products include halides, halide salts, and organic compounds that are sticky and resistant to removal. Buildup of residual etch products can lead to process drift, resulting in hazard precautions in the process chamber. Exposure to the second plasma may quickly remove such residual impurities and contaminants. Exposure to the second plasma recovers the one or more internal surfaces of the process chamber to be free or substantially free of residual organic material, residual gases, and other contaminants.

A chemistry of the second plasma is different than a chemistry of the first plasma. A second process gas, which is different than the first process gas, may be flowed to the process chamber or a remote plasma source for igniting the second plasma. In some embodiments, the second process gas includes one or both of an oxygen-containing species and a hydrogen-containing species. In some embodiments, the second process gas for generating the second plasma may include oxygen (O₂), ozone (O₃), hydrogen (H₂), water (H₂O), hydrogen peroxide (H₂O₂), methane (CH₄), or mixtures thereof. As such, the second plasma may include one or both of an oxygen-containing plasma and hydrogen-containing plasma. For instance, the second plasma may include an O₂ plasma, O₃ plasma, H₂ plasma, H₂O plasma, H₂O₂ plasma, CH₄ plasma, or mixtures thereof.

In some embodiments, the second plasma is generated directly in the process chamber. The second process gas may be flowed into the process chamber and distributed throughout the process chamber. RF power may be applied to the process chamber to generate the second plasma comprising plasma-activated species (e.g., radicals/ions) of the second process gas. The second plasma may be generated by ICP generation, TCP generation, CCP generation, or other methods known in the art. The second plasma may be controlled to be preferentially directed towards the one or more internal surfaces of the process chamber.

In some embodiments, the second plasma is generated in a remote plasma source coupled to the process chamber. The second process gas may be flowed into the remote plasma source where RF power is applied to the remote plasma source to generate plasma-activated species (e.g., radicals/ions) of the second process gas. The second plasma may be generated using ICP, TCP, CCP, or other plasma technique known in the art. The second plasma may be delivered from the remote plasma source into the process chamber so that the plasma-activated species are distributed towards the one or more internal surfaces of the process chamber. In some embodiments, the second plasma is delivered from the remote plasma source into the process chamber through a showerhead. Additionally or alternatively, the second plasma is delivered from the remote plasma source into the process chamber through a distributor that preferentially directs the second plasma to the one or more internal surfaces of the process chamber.

Process conditions for applying the second plasma may be controlled to remove residual gases, residual organic material, and/or other contaminants in the process chamber. In some implementations, the second process gas may have a different composition than the first process gas. In particular, the first process gas may include a halide-containing chemistry such as Cl₂ and the second process gas may include O₂ or H₂. In some implementations, second process gas flow may be between about 50 sccm and about 10000 sccm or between about 100 sccm and about 5000 sccm. In some implementations, a temperature may be between about −60° C. and about 140° C., between about −20° C. and about 120° C., or between about 20° C. and about 100° C. In some implementations, chamber pressure may be between about 1 mTorr and about 20 Torr, between about 5 mTorr and about 5 Torr, or between about 5 mTorr and about 100 mTorr. In some implementations, plasma power may be between about 50 W and about 6000 W, between about 100 W and about 3000 W, or between about 100 W and about 800 W. In some implementations, the wafer bias is between about 0 V and about 500 V, between about 10 V and about 300 V, or between about 20 V and about 200 V. The plasma may be generated using a high RF frequency. In some implementations, the RF frequency is 13.56 MHz, 400 kHz, 2 MHz, 2.45 GHz, or 40 MHz. In some implementations, the duration of exposure to the second plasma is between about 2 seconds and about 2000 seconds, between about 5 seconds and about 1000 seconds, or between about 10 seconds and about 500 seconds.

The second plasma may be configured to remove any residual carbon from the organometallic material. Further, the second plasma may be configured to remove any residual gas such as residual halides/halogens used to remove the organometallic material. Oxidizing gas, for example, may be introduced to oxidize residual halides/halogens such as Cl or Br on internal chamber surfaces. Oxidizing gas may also be effective in removing remaining organic material such as carbon-containing residues on internal chamber surfaces. Applying plasma of the oxidizing gas further accelerates removal of the residual halides/halogens and organic material.

In some embodiments, applying heat with the second plasma may further accelerate removal of residual gas, residual carbon, and/or other contaminants in the process chamber. Higher temperatures may cause certain residues to volatilize. As such, thermal energy may be applied to drive reactions to remove residual gas, residual carbon, and/or other contaminants. One or more heaters may be controlled to adjust the temperature of the one or more internal surfaces of the process chamber. The one or more heaters may adjust the temperature of the one or more internal surfaces to an elevated temperature equal to or greater than 20° C. to drive removal of the residual gas, residual carbon, and/or other contaminants.

In some embodiments, purging may follow exposure to the second plasma to remove excess contaminants. Purging may comprise flowing an inert gas and/or reactive gas into the process chamber. Residual gases may be exhausted from the process chamber by purging. In some embodiments, the purge operation may also be referred to as dehalogenation. Purge gas may be flowed into the process chamber to facilitate removal of unwanted particles in the process chamber. Such unwanted particles may include particles or flakes from the organometallic material or byproducts. A vacuum pump system may reduce a chamber pressure and/or remove unwanted particles from the process chamber. Thus, dry chamber cleaning may proceed from a combination of thermal, plasma, and purge processes.

In some implementations, the process 200 may further include optionally conditioning the one or more internal surfaces of the process chamber with a protective coating. This process may also be referred to as chamber “seasoning.” In some embodiments, the protective coating may include organometallic material. An average thickness of the protective coating may be equal to or greater than 1 nm, equal to or greater than 2 nm, equal to or greater than 3 nm, or between about 1 nm and about 5 nm. After the thermal and/or plasma processes for performing dry chamber clean, exposed surfaces of the process chamber may be vulnerable to attack, especially by halogen-based species. The conditioning operation may provide protection of the one or more internal surfaces. In some implementations, conditioning the one or more internal surfaces may occur by a vapor-based deposition technique such as CVD or ALD. By conditioning/seasoning the process chamber, undesirable first wafer effects are mitigated when re-initiating deposition operations on semiconductor substrates.

FIG. 3F shows a cross-sectional schematic illustration of the process chamber during dry chamber cleaning with a second plasma. The internal surfaces of the process chamber 300 may be exposed to a second plasma 340 to remove residual contaminants 314 or other impurities. Following a plasma process using the first plasma 330 to remove the residue 312, dry chamber cleaning may proceed with another plasma process using the second plasma 340 to remove the residual contaminants 314. A chemistry of the first plasma 330 may be different than a chemistry of the second plasma 340. Exposure to the second plasma 340 may occur without the semiconductor substrate 308 in the process chamber 300.

The second plasma 340 may include radicals and/or ions of an oxygen-containing gas, a hydrogen-containing gas, or mixtures thereof. In some implementations, the second plasma 340 includes plasma-activated species of O₂, O₃, H₂, H₂O, H₂O₂, CH₄, or mixtures thereof. For instance, the second plasma 340 includes plasma-activated species of O₂, where such plasma-activated species may include oxygen radicals (O*). The plasma-activated species of the oxygen-containing gas and/or hydrogen-containing gas may provide reactive species for etching the residual contaminants 314.

In some embodiments, the second plasma 340 is generated directly in the process chamber 300. In some embodiments, the second plasma 340 is generated in a remote plasma source (not shown) that is separate from the process chamber 300 but fluidly coupled to the process chamber 300. The second plasma 340 may be configured to remove residual gases such as residual halides/halogens. Also, the second plasma 340 may be configured to remove remaining organic material as well as any unremoved portions of the metal-containing material. The residual contaminants 314 may comprise any of the aforementioned residual materials.

FIG. 4D shows a cross-sectional schematic illustration of the chamber walls 404 after plasma exposure removes the residual etch gas 408 and the residual organic material 410 from the chamber walls 404. A secondary plasma may be generated that is configured to remove the residual etch gas 408 and the residual organic material 410, where the secondary plasma may be different than the primary plasma for removing the residue 406 from the chamber walls 404. In some cases, the secondary plasma may include an oxygen-containing gas such as oxygen or ozone, a hydrogen-containing gas such as hydrogen, or mixtures thereof. In some embodiments, pumping/purging operations may be performed to remove contaminants from such as the residual etch gas 408 and the residual organic material 410 from the process chamber.

In the present disclosure as discussed above, the removal of unintended metal-containing photoresist material may proceed by dry chamber clean using a hybrid thermal and plasma approach. In such cases, the removal of the unintended metal-containing material occurs using a multi-step clean process involving a thermal process and a plasma process. The thermal process may remove portions of the metal-containing material and modify other portions of the metal-containing material, and the plasma process may remove or at least substantially remove the modified portions of the metal-containing material. Alternatively, as described below with respect to FIG. 2B, the plasma process may remove portions of the metal-containing material and modify other portions of the metal-containing material, and the thermal process may remove or at least substantially remove the modified portions of the metal-containing material. In some embodiments, the thermal process may involve a halide-based thermal clean without striking a plasma. In some embodiments, the plasma process may involve a halide-based plasma clean followed by an oxygen-based or hydrogen-based plasma process. In some embodiments, exposed surfaces of the process chamber may be conditioned to protect chamber surfaces from attack. In some implementations, the plasma process may remove the metal-containing material or at least substantially remove the metal-containing material. In such instances, a subsequent thermal process is unnecessary.

FIG. 2B presents a flow diagram of an alternative example method of performing a dry chamber clean using plasma processes, or plasma and thermal processes, according to some implementations. The operations of a process 250 may be performed in different orders and/or with different, fewer, or additional operations. One or more operations of the process 250 may be performed using an apparatus described in any one of FIGS. 5-8. In some implementations, the operations of the process 250 may be implemented, at least in part, according to software stored in one or more non-transitory computer readable media.

At block 252 of the process 250, a semiconductor substrate with a metal-containing resist film on a surface of the semiconductor substrate is provided in a process chamber. In addition, organometallic material is formed on one or more internal surfaces of the process chamber. The organometallic material formed on the one or more internal surfaces of the process chamber may have the same or similar chemical composition as the metal-containing resist film on the semiconductor substrate. Aspects of block 252 of the process 250 are described above at block 202 of the process 200.

At block 254 of the process 250, the one or more internal surfaces of the process chamber are exposed to a first plasma to remove first portions of the organometallic material without the semiconductor substrate in the process chamber. Some of the other portions may be converted or otherwise modified by exposure to the first plasma. Modified portions of the organometallic material may constitute nonvolatile etch byproducts of unremoved portions of the organometallic material. The first plasma may include a halide-containing plasma, hydrogen-containing plasma, hydrocarbon-containing plasma, inert gas-containing plasma, or mixtures thereof. Plasma-activated species of the first plasma may react with the first portions of the organometallic material to form volatile products and nonvolatile products. The volatile products may be removed from the process chamber while the nonvolatile products remain as residue to be subsequently removed by a thermal process.

A first process gas may be flowed to the process chamber or to a remote plasma source for igniting the first plasma. In some instances, the first process gas includes a halide-containing gas. In some embodiments, the first plasma is generated directly in the process chamber. In some embodiments, the first plasma is generated remotely in a remote plasma source fluidly coupled to the process chamber.

Exposure to the first plasma may remove and/or modify the organometallic material. In some cases, the first portions of the organometallic material removed by the first plasma may represent a bulk or a substantial fraction of the organometallic material. In some other cases, however, the first portions of the organometallic material removed by the first plasma may represent less than a bulk of the organometallic material. The first plasma may convert or otherwise modify a bulk or a substantial fraction of the organometallic material. Converted or modified organometallic material may be more easily removable by non-plasma etch gas as discussed below.

Process conditions for applying the first plasma may be controlled to remove the first portions of the organometallic material. In some implementations, the first process gas for the first plasma is composed of a halide-containing chemistry. In one example, the first process gas for the first plasma may include HBr, Cl₂, BCl₃, or a mixture of Cl₂ and BCl₃. In some implementations, the first process gas for the first plasma is composed of a hydrocarbon-containing chemistry. For example, the first process gas for the first plasma may include CH₄. In some implementations, the first process gas for the first plasma is composed of a halide-containing chemistry, a hydrocarbon-containing chemistry, an inert gas, or a mixture thereof. In one example, the first process gas for the first plasma may include Cl₂, CH₄, Ar, or a mixture thereof. In another example, the first process gas for the first plasma may include HBr, Ar, or a mixture thereof. In some implementations, first process gas flow may be between about 50 sccm and about 10000 sccm or between about 100 sccm and about 5000 sccm. In some implementations, a temperature may be between about −60° C. and about 120° C., between about −20° C. and about 100° C., between about −60° C. and about 60° C., or between about 20° C. and about 100° C. In some implementations, chamber pressure may be between about 1 mTorr and about 20 Torr, between about 5 mTorr and about 760 Torr, or between about 5 m Torr and about 100 mTorr. In some implementations, plasma power may be between about 50 W and about 6000 W, between about 100 W and about 3000 W, or between about 100 W and about 800 W. In some implementations, the wafer bias is between about 0 V and about 500 V, between about 10 V and about 300 V, or between about 20 V and about 200 V. The plasma may be generated using a high RF frequency. In some implementations, the RF frequency is 13.56 MHz, 400 kHz, 2 MHz, 2.45 GHz, or 40 MHz. In some implementations, the duration of exposure to the first plasma is between about 5 seconds and about 3000 seconds, between about 10 seconds and about 2000 seconds, or between about 30 seconds and about 1200 seconds.

Prior to exposure to the first plasma, the process chamber may be prepared with desired conditions for dry chamber cleaning. In some embodiments, preparing the process chamber may include removing the semiconductor substrate from the process chamber. That way, the process chamber may be free of the semiconductor substrate or any other processing substrate during dry chamber cleaning. Thus, the semiconductor substrate having the metal-containing resist film may be transferred out of the process chamber prior to dry chamber cleaning. In some embodiments, preparing the process chamber may include providing a dummy substrate on a substrate support in the process chamber. Alternatively, protection of the substrate support may occur by providing a protective cover over the substrate support during dry chamber cleaning. In some embodiments, preparing the process chamber may include purging and/or pumping the process chamber to remove unwanted particles in the process chamber. In some embodiments, preparing the process chamber may include increasing a temperature of one or more internal surfaces in the process chamber.

At block 256 of the process 250, the one or more internal surfaces of the process chamber may be exposed to a non-plasma etch gas to remove second portions of the organometallic material without the semiconductor substrate in the process chamber. Following a plasma process that removes the first portions of the organometallic material and converts some other portions of the organometallic material, a thermal process may follow that removes or substantially removes the some other portions of the organometallic material that were converted. The second portions may constitute the converted organometallic material. The non-plasma etch gas may be configured to form volatile products with the second portions of the organometallic material. In some embodiments, the non-plasma etch gas may include a halide-containing gas. In some embodiments, the halide-containing gas may include a hydrogen halide such as HF, HCl, HBr, HI, or combinations thereof. In some embodiments, the halide-containing gas may include BCl₃, BBr₃, or mixtures thereof. In some embodiments, the etch gas is flowed with or without inert/carrier gas such as He, Ne, Ar, Xe, or N₂.

Exposure to the etch gas to remove or substantially remove the second portions of the organometallic material may be done without plasma. Exposure to the non-plasma etch gas may proceed by heating the one or more internal surfaces of the process chamber to an elevated temperature. One or more heaters may be thermally coupled to the one or more surfaces of the process chamber to heat the one or more surfaces to an elevated temperature. In some embodiments, the elevated temperature may be between about −15° C. and about 200° C., between about −15° C. and about 140° C., or between about 0° C. and about 120° C. Higher temperatures may promote volatility of etch byproducts. By applying a plasma-free thermal approach, productivity can be significantly improved.

The non-plasma etch gas may react with the second portions of the organometallic material to form volatile products. The non-plasma etch gas may be delivered into the process chamber through a distributor or other gas inlet(s) that preferentially directs the non-plasma etch gas to the one or more internal surfaces of the process chamber.

The non-plasma etch gas may be configured to remove any re-deposited and decomposed organometallic material remaining in the process chamber. The second portions of the organometallic material may be composed of nonvolatile salts or byproducts. The non-plasma etch gas may be configured with a suitable chemistry and reactivity to react with the second portions of the organometallic material to form volatile byproduct(s).

The process chamber is free of the semiconductor substrate during thermal exposure. In some embodiments, the process chamber may include a dummy substrate on a substrate support in the process chamber. The dummy substrate may be provided on the substrate support to protect the substrate support (e.g., electrostatic chuck) from exposure to non-plasma etch gas during dry chamber cleaning. Alternatively, protection of the substrate support may occur by providing a protective cover over the substrate support during dry chamber cleaning.

Though the process 250 is illustrated with a plasma-free thermal process at block 256, the process 250 of dry chamber clean may proceed without the plasma-free thermal process at block 256. In other words, the dry chamber clean may remove the organometallic material from the one or more internal surfaces of the process chamber using the first plasma, or using the first plasma and the second plasma (described below) Accordingly, dry chamber clean may be accomplished using a plasma-only approach.

In some implementations, at block 258 of the process 250, the one or more internal surfaces of the process chamber are optionally exposed to a second plasma to remove one or both of residual gases and residual organic material from the process chamber. In some embodiments, the second plasma may additionally remove residual salts and other contaminants from the process chamber. Following exposure to the first plasma, or exposure to the first plasma and the non-plasma etch gas, some residual impurities or contaminants may still remain in the process chamber. Exposure to the second plasma may quickly remove such residual impurities and contaminants.

A chemistry of the second plasma is different than a chemistry of the first plasma. A second process gas, which is different than the first process gas, may be flowed to the process chamber or a remote plasma source for igniting the second plasma. In some embodiments, the second process gas includes one or both of an oxygen-containing species and a hydrogen-containing species. In some embodiments, the second process gas for generating the second plasma may include oxygen (O₂), ozone (O₃), hydrogen (H₂), water (H₂O), hydrogen peroxide (H₂O₂), methane (CH₄), or mixtures thereof. As such, the second plasma may include one or both of an oxygen-containing plasma and hydrogen-containing plasma. For instance, the second plasma may include an O₂ plasma, O₃ plasma, H₂ plasma, H₂O plasma, H₂O₂ plasma, CH₄ plasma, or mixtures thereof.

In some embodiments, the second plasma is generated directly in the process chamber. The second process gas may be flowed into the process chamber and distributed throughout the process chamber. RF power may be applied to the process chamber to generate the second plasma comprising plasma-activated species (e.g., radicals/ions) of the second process gas. The second plasma may be generated by ICP generation, TCP generation, CCP generation, or other methods known in the art. The second plasma may be controlled to be preferentially directed towards the one or more internal surfaces of the process chamber.

In some embodiments, the second plasma is generated in a remote plasma source coupled to the process chamber. The second process gas may be flowed into the remote plasma source where RF power is applied to the remote plasma source to generate plasma-activated species (e.g., radicals/ions) of the second process gas. The second plasma may be generated using ICP, TCP, CCP, or other plasma technique known in the art. The second plasma may be delivered from the remote plasma source into the process chamber so that the plasma-activated species are distributed towards the one or more internal surfaces of the process chamber. In some embodiments, the second plasma is delivered from the remote plasma source into the process chamber through a showerhead. Additionally or alternatively, the second plasma is delivered from the remote plasma source into the process chamber through a distributor that preferentially directs the second plasma to the one or more internal surfaces of the process chamber.

Process conditions for applying the second plasma may be controlled to remove residual gases, residual organic material, and/or other contaminants in the process chamber. In some implementations, the second process gas may have a different composition than the first process gas. In particular, the first process gas may include a halide-containing chemistry such as Cl₂ and the second process gas may include O₂ or H₂. In some implementations, second process gas flow may be between about 50 sccm and about 10000 sccm or between about 100 sccm and about 5000 sccm. In some implementations, a temperature may be between about −60° C. and about 140° C., between about −20° C. and about 120° C., or between about 20° C. and about 100° C. In some implementations, chamber pressure may be between about 1 mTorr and about 20 Torr, between about 5 mTorr and about 5 Torr, or between about 5 mTorr and about 100 mTorr. In some implementations, plasma power may be between about 50 W and about 6000 W, between about 100 W and about 3000 W, or between about 100 W and about 800 W. In some implementations, the wafer bias is between about 0 V and about 500 V, between about 10 V and about 300 V, or between about 20 V and about 200 V. The plasma may be generated using a high RF frequency. In some implementations, the RF frequency is 13.56 MHz, 400 kHz, 2 MHz, 2.45 GHz, or 40 MHz. In some implementations, the duration of exposure to the second plasma is between about 2 seconds and about 2000 seconds, between about 5 seconds and about 1000 seconds, or between about 10 seconds and about 500 seconds.

The second plasma may be configured to remove any residual carbon from the organometallic material. Further, the second plasma may be configured to remove any residual gas such as residual halides/halogens used to remove the organometallic material. Oxidizing gas, for example, may be introduced to oxidize residual halides/halogens such as Cl or Br on internal chamber surfaces. Oxidizing gas may also be effective in removing remaining organic material such as carbon-containing residues on internal chamber surfaces. Applying plasma of the oxidizing gas further accelerates removal of the residual halides/halogens and organic material.

In some embodiments, applying heat with the second plasma may further accelerate removal of residual gas, residual carbon, and/or other contaminants in the process chamber. Higher temperatures may cause certain residues to volatilize. As such, thermal energy may be applied to drive reactions to remove residual gas, residual carbon, and/or other contaminants. One or more heaters may be controlled to adjust the temperature of the one or more internal surfaces of the process chamber. The one or more heaters may adjust the temperature of the one or more internal surfaces to an elevated temperature equal to or greater than 20° C. to drive removal of the residual gas, residual carbon, and/or other contaminants.

In some embodiments, purging may follow exposure to the second plasma to remove excess contaminants. Purging may comprise flowing an inert gas and/or reactive gas into the process chamber. Residual gases may be exhausted from the process chamber by purging. In some embodiments, the purge operation may also be referred to as dehalogenation. Purge gas may be flowed into the process chamber to facilitate removal of unwanted particles in the process chamber. Such unwanted particles may include particles or flakes from the organometallic material or byproducts. A vacuum pump system may reduce a chamber pressure and/or remove unwanted particles from the process chamber. Thus, dry chamber cleaning may proceed from a combination of thermal, plasma, and purge processes.

In some implementations, the process 250 may further include optionally conditioning the one or more internal surfaces of the process chamber with a protective coating. In some embodiments, the protective coating may include organometallic material. An average thickness of the protective coating may be equal to or greater than 1 nm, equal to or greater than 2 nm, equal to or greater than 3 nm, or between about 1 nm and about 5 nm. After the thermal and/or plasma processes for performing dry chamber clean, exposed surfaces of the process chamber may be vulnerable to attack, especially by halogen-based species. The conditioning operation may provide protection of the one or more internal surfaces. In some implementations, conditioning the one or more internal surfaces may occur by a vapor-based deposition technique such as CVD or ALD. By conditioning/seasoning the process chamber, undesirable first wafer effects are mitigated when re-initiating deposition operations on semiconductor substrates.

Various implementations of the present disclosure may include combining all dry operations by vapor deposition, EUV lithographic patterning, dry development, and dry chamber clean. Various other implementations include a combination of wet and dry processing operations, for example, spin-on EUV photoresists (wet process) may be combined with dry chamber clean or other wet or dry processes as described herein. Also described are various post-deposition (or post-application) processes such as bevel and backside cleaning, chamber cleaning, descum, smoothing, curing to modify and enhance film characteristics, and photoresist rework processing. Utilizing all dry operations, including dry chamber clean, may have particular advantages. Such dry processing operations may avoid material and productivity costs associated with wet processing operations such as wet chamber clean or wet development.

While this disclosure frequently refers to the cleaning of EUV-sensitive films that have been exposed and/or developed, the cleaning processes described can be extended to EUV films of similar composition (e.g., other MOₓR_{y}-based films), for example, other films containing a metal oxide, in which the metal can form volatile products with —Cl, —Br, —F, —H, —CH₄, etc., as described herein, including unexposed EUV resist films. Additionally, in some embodiments, films other than EUV resists can be cleaned by this method, for example hard masks, UV resists or films of similar composition having other applications; in this respect, the described cleaning process relates to the film's chemical composition, as opposed to its function.

### Apparatus

An apparatus of the present disclosure is configured for dry chamber clean such as an in-situ dry chamber clean. The apparatus may be configured for other processing operations such as deposition, bevel and backside cleaning, post-application baking, EUV scanning, development, post-exposure baking, photoresist reworking, descum, smoothing, curing, and other operations. In some implementations, the apparatus is configured to perform all dry operations. In some implementations, the apparatus is configured to perform a combination of wet and dry operations. The apparatus may include a single wafer chamber or multiple stations in the same process chamber. With multiple stations in the same process chamber, various processing operations such as those described in the present disclosure may be performed in different stations in the same process chamber. In one example, PEB thermal treatment may be performed in one station and development in another station.

The apparatus configured for dry chamber clean includes a process chamber with a substrate support. The substrate support may be configured to support a semiconductor substrate having a metal-containing resist film formed thereon. The apparatus may include a gas line coupled to the process chamber for delivery of etch gas. In some implementations, the etch gas includes a hydrogen halide such as HBr. The apparatus may include a vacuum line coupled to the process chamber. The vacuum line may be configured for pumping/purging of gas from the process chamber. The apparatus may include one or more heaters for temperature control. Such heaters may be provided in the process chamber and/or in the substrate support. In some implementations, there may be multiple gas inlets positioned within the process chamber to flow etch gas near regions where unintended metal-containing material tend to form. The apparatus may further include one or more sensors for sensing particle count, wafer count, thickness count, or other parameters for triggering the dry chamber clean and/or endpoint of the dry chamber clean.

In some implementations, the process chamber is made of an inexpensive material such as plastic. In some other implementations, the process chamber is made of a metal such as anodized aluminum or a ceramic such as aluminum oxide.

In some implementations, the process chamber for performing dry chamber clean may be selected from a group consisting of: a dry deposition chamber, a bevel edge and/or backside clean chamber, a bake chamber, an exposure chamber, a dry development chamber, or etch chamber. The dry chamber clean may be performed in-situ with other substrate processing operations when processing photoresist material. The process chamber for performing dry chamber clean may be configured for a clean involving one or more plasma processes. The process chamber for performing dry chamber clean may be configured for a multi-step clean involving a thermal process and plasma process. Accordingly, the process chamber may be equipped for plasma generation to expose internal chamber surfaces to plasma and may also be equipped for delivery of etch gas to expose internal chamber surfaces to thermal etch gas.

FIG. 5 depicts a schematic illustration of an example process station that is suitable for performing dry chamber clean, dry development, bevel edge and/or backside clean, etch, rework, descum, and smoothing operations according to some implementations. A plurality of process stations 500 may be included in a common low-pressure process tool environment. For example, FIG. 6 depicts an implementation of a multi-station processing tool 600, such as a VECTOR® processing tool available from Lam Research Corporation, Fremont, CA. In some implementations, one or more hardware parameters of the process tool 600 including those discussed in detail below may be adjusted programmatically by one or more computer controllers 650.

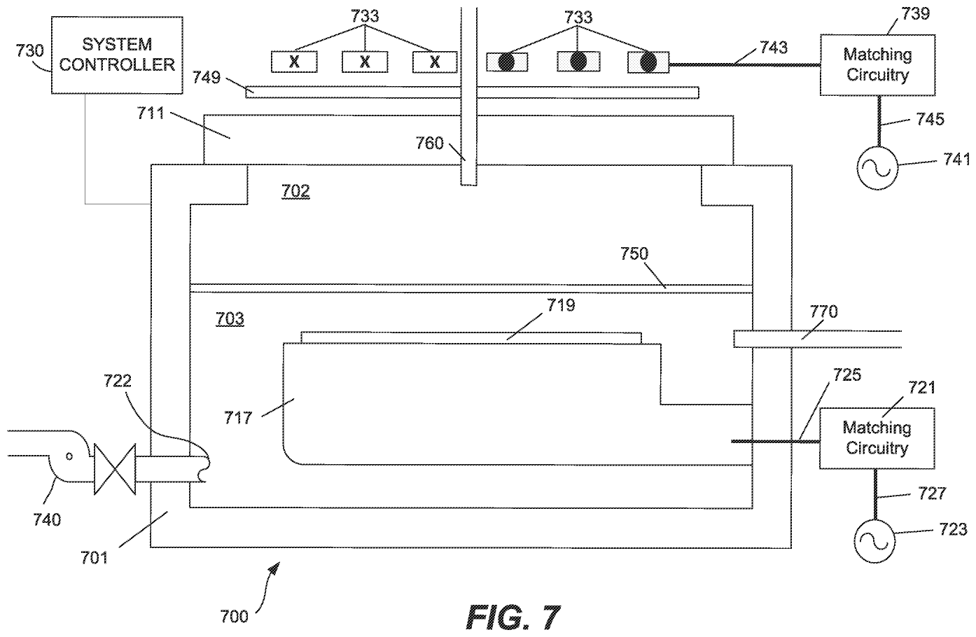

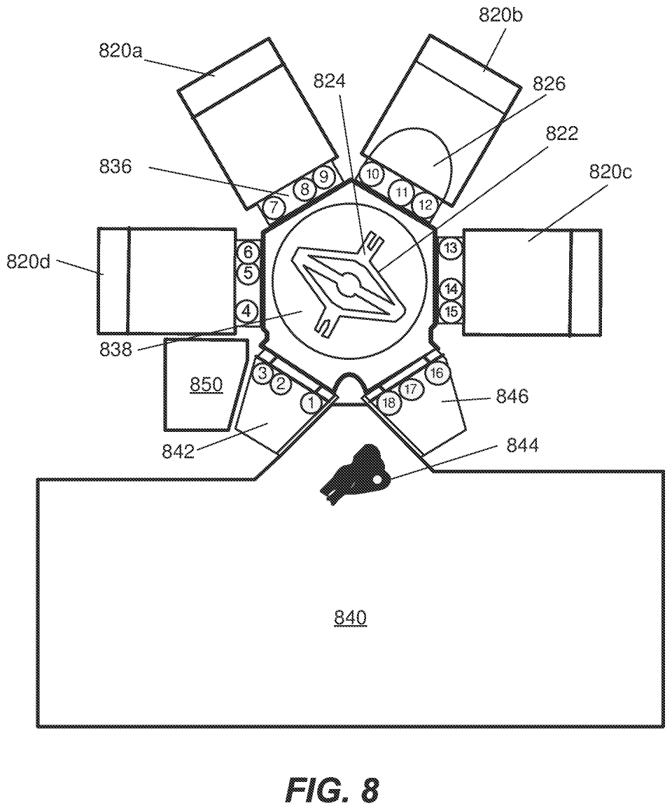

A process station may be configured as a module in a cluster tool. FIG. 6 depicts a semiconductor process cluster tool architecture with vacuum-integrated deposition and patterning modules suitable for implementation of the implementations described herein. Such a cluster process tool architecture can include resist deposition, resist exposure (EUV scanner), resist development and etch modules, as described above and further below with reference to FIGS. 7 and 8.

In some implementations, certain of the processing functions can be performed consecutively in the same module, for example dry development and etch or dry deposition and dry chamber clean. And implementations of this disclosure are directed to methods and apparatus for receiving a wafer, including an EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 5, process station 500 fluidly communicates with reactant delivery system 501a for delivering process gases to a distribution showerhead 506. Reactant delivery system 501a optionally includes a mixing vessel 504 for blending and/or conditioning process gases, for delivery to showerhead 506. One or more mixing vessel inlet valves 520 may control introduction of process gases to mixing vessel 504. Where plasma exposure is used, plasma may also be delivered to the showerhead 506 or may be generated in the process station 500.

FIG. 5 includes an optional vaporization point 503 for vaporizing liquid reactant to be supplied to the mixing vessel 504. In some implementations, a liquid flow controller (LFC) upstream of vaporization point 503 may be provided for controlling a mass flow of liquid for vaporization and delivery to process station 500. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 506 distributes process gases toward substrate 512. In the implementation shown in FIG. 5, the substrate 512 is located beneath showerhead 506 and is shown resting on a pedestal 508. Showerhead 506 may have any suitable shape, and may have any suitable number and arrangement of ports for distributing process gases to substrate 512.

In some implementations, pedestal 508 may be raised or lowered to expose substrate 512 to a volume between the substrate 512 and the showerhead 506. It will be appreciated that, in some implementations, pedestal height may be adjusted programmatically by a suitable computer controller 550. In some implementations, the showerhead 506 may have multiple plenum volumes with multiple temperature controls.

In some implementations, pedestal 508 may be temperature controlled via heater 510. In some implementations, the pedestal 508 may be heated to a temperature of greater than −20° C. and up to 300° C. or more, for example 40° C. to 160° C., such as about 80° C. to 140° C., during non-plasma thermal exposure as described in disclosed implementations. In some implementations, the heater 510 of the pedestal 508 may include a plurality of independently controllable temperature control zones.

Further, in some implementations, pressure control for process station 500 may be provided by a butterfly valve 518. As shown in the implementation of FIG. 5, butterfly valve 518 throttles a vacuum provided by a downstream vacuum pump (not shown). However, in some implementations, pressure control of process station 500 may also be adjusted by varying a flow rate of one or more gases introduced to the process station 500.

In some implementations, a position of showerhead 506 may be adjusted relative to pedestal 508 to vary a volume between the substrate 512 and the showerhead 506. Further, it will be appreciated that a vertical position of pedestal 508 and/or showerhead 506 may be varied by any suitable mechanism within the scope of the present disclosure. In some implementations, pedestal 508 may include a rotational axis for rotating an orientation of substrate 512. It will be appreciated that, in some implementations, one or more of these example adjustments may be performed programmatically by one or more suitable computer controllers.

Where plasma may be used, for example in dry chamber clean operations, showerhead 506 and/or pedestal 508 electrically communicate with a radio frequency (RF) power supply 514 and matching network 516 for powering a plasma. Thus, one or both of the showerhead 506 and the pedestal 508 may be powered for plasma generation. In some implementations, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are up to about 6000 W, up to about 3000 W, or up to about 1000 W.

In some implementations, instructions for a controller may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some implementations, instructions for setting one or more reactor parameters may be included in a recipe phase. For example, a recipe phase may include instructions for setting a flow rate of an etch gas, such as HBr, and time delay instructions for the recipe phase. In some implementations, the controller may include any of the features described below with respect to system controller 650 of FIG. 6.

As described above, one or more process stations may be included in a multi-station processing tool. FIG. 6 shows a schematic view of an implementation of a multi-station processing tool 600 with an inbound load lock 602 and an outbound load lock 604, either or both of which may include a remote plasma source. A robot 606 at atmospheric pressure is configured to move wafers from a cassette loaded through a pod 608 into inbound load lock 602 via an atmospheric port 610. A wafer is placed by the robot 606 on a pedestal 612 in the inbound load lock 602, the atmospheric port 610 is closed, and the load lock is pumped down. Where the inbound load lock 602 includes a remote plasma source, the wafer may be exposed to a remote plasma treatment to treat the substrate surface in the load lock prior to being introduced into a processing chamber 614. Further, the wafer also may be heated in the inbound load lock 602 as well, for example, to remove moisture and adsorbed gases. Next, a chamber transport port 616 to processing chamber 614 is opened, and another robot (not shown) places the wafer into the reactor on a pedestal of a first station shown in the reactor for processing. While the implementation depicted in FIG. 6 includes load locks, it will be appreciated that, in some implementations, direct entry of a wafer into a process station may be provided.

The depicted processing chamber 614 includes four process stations, numbered from 1 to 4 in the implementation shown in FIG. 6. Each station has a heated pedestal (shown at 618 for station 1), and gas line inlets. It will be appreciated that in some implementations, each process station may have different or multiple purposes. For example, in some implementations, a process station may be switchable between thermal and plasma process modes. Additionally or alternatively, in some implementations, processing chamber 614 may include one or more matched pairs of thermal and plasma process stations. While the depicted processing chamber 614 includes four stations, it will be understood that a processing chamber according to the present disclosure may have any suitable number of stations. For example, in some implementations, a processing chamber may have five or more stations, while in other implementations a processing chamber may have three or fewer stations.

FIG. 6 depicts an implementation of a wafer handling system 690 for transferring wafers within processing chamber 614. In some implementations, wafer handling system 690 may transfer wafers between various process stations and/or between a process station and a load lock. It will be appreciated that any suitable wafer handling system may be employed. Non-limiting examples include wafer carousels and wafer handling robots. FIG. 6 also depicts an implementation of a system controller 650 employed to control process conditions and hardware states of process tool 600. System controller 650 may include one or more memory devices 656, one or more mass storage devices 654, and one or more processors 652. Processor 652 may include a CPU or computer, analog, and/or digital input/output connections, stepper motor controller boards, etc.

In some implementations, system controller 650 controls all of the activities of process tool 600. System controller 650 executes system control software 658 stored in mass storage device 654, loaded into memory device 656, and executed on processor 652. Alternatively, the control logic may be hard coded in the controller 650. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 658 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 600. System control software 658 may be configured in any suitable way. For example, various process tool component subroutines or control objects may be written to control operation of the process tool components used to carry out various process tool processes. System control software 658 may be coded in any suitable computer readable programming language.

In some implementations, system control software 658 may include input/output control (IOC) sequencing instructions for controlling the various parameters described above. Other computer software and/or programs stored on mass storage device 654 and/or memory device 656 associated with system controller 650 may be employed in some implementations. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling process gas (e.g., etch gas) composition and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate or internal chamber surfaces. Alternatively, the heater control program may control delivery of a heat transfer gas (such as helium) to the substrate or internal chamber surfaces.

A plasma control program may include code for setting RF power levels applied to the process electrodes in one or more process stations in accordance with the implementations herein.

A pressure control program may include code for maintaining the pressure in the reaction chamber in accordance with the implementations herein.

In some implementations, there may be a user interface associated with system controller 650. The user interface may include a display screen, graphical software displays of the apparatus and/or process conditions, and user input devices such as pointing devices, keyboards, touch screens, microphones, etc.

In some implementations, parameters adjusted by system controller 650 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

In some implementations, the system controller 650 may be configured with instructions to perform the following operations: provide, in the process chamber, a semiconductor substrate, wherein organometallic material is formed on one or more internal surfaces of the processing chamber 614; expose, without the semiconductor substrate in the processing chamber 614, the one or more internal surfaces of the processing chamber 614 to a non-plasma etch gas to remove first portions of the organometallic material; and expose, without the semiconductor substrate in the processing chamber 614, the one or more internal surfaces of the processing chamber 614 to a first plasma to remove second portions of the organometallic material. In some implementations, the system controller 650 may be further configured with instructions to expose the one or more internal surfaces of the processing chamber 614 to a second plasma to remove one or both of residual gases and residual organic material from the processing chamber 614.

Signals for monitoring the process may be provided by analog and/or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 650 may provide program instructions for implementing the above-described deposition processes. The program instructions may control a variety of process parameters, such as DC power level, RF bias power level, pressure, temperature, etc. The instructions may control the parameters to operate development, clean, and/or etch processes according to various implementations described herein.

The system controller 650 will typically include one or more memory devices and one or more processors configured to execute the instructions so that the apparatus will perform a method in accordance with disclosed implementations. Machine-readable media containing instructions for controlling process operations in accordance with disclosed implementations may be coupled to the system controller 650.

In some implementations, the system controller 650 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 650, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 650 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 650 in the form of various individual settings (or program files), defining operational parameters for carrying out a particular process on or for a semiconductor wafer or to a system. The operational parameters may, in some implementations, be part of a recipe defined by process engineers to accomplish one or more processing steps during the fabrication of one or more layers, materials, metals, oxides, silicon, silicon dioxide, surfaces, circuits, and/or dies of a wafer.

The system controller 650, in some implementations, may be a part of or coupled to a computer that is integrated with, coupled to the system, otherwise networked to the system, or a combination thereof. For example, the system controller 650 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 650 receives instructions in the form of data, which specify parameters for each of the processing steps to be performed during one or more operations. It should be understood that the parameters may be specific to the type of process to be performed and the type of tool that the system controller 650 is configured to interface with or control. Thus as described above, the system controller 650 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a development chamber or module, and any other semiconductor processing systems that may be associated or used in the fabrication and/or manufacturing of semiconductor wafers.

As noted above, depending on the process step or steps to be performed by the tool, the system controller 650 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

ICP reactors which, in certain implementations, may be suitable for etch operations suitable for implementation of some implementations, are now described. Although ICP reactors are described herein, in some implementations, it should be understood that capacitively coupled plasma reactors may also be used.

FIG. 7 schematically shows a cross-sectional view of an inductively coupled plasma apparatus 700 appropriate for implementing certain implementations or aspects of implementations such as dry development, clean, and/or etch, an example of which is a Kiyo® reactor, produced by Lam Research Corp. of Fremont, CA. In other implementations, other tools or tool types having the functionality to conduct the dry development, clean, and/or etch processes described herein may be used for implementation.

The inductively coupled plasma apparatus 700 includes an overall process chamber 724 structurally defined by chamber walls 701 and a window 711. The chamber walls 701 may be fabricated from stainless steel, aluminum, or plastic. The window 711 may be fabricated from quartz or other dielectric material. An optional internal plasma grid 750 divides the overall process chamber into an upper sub-chamber 702 and a lower sub chamber 703. In most implementations, plasma grid 750 may be removed, thereby utilizing a chamber space made of sub chambers 702 and 703. A chuck 717 is positioned within the lower sub-chamber 703 near the bottom inner surface. The chuck 717 is configured to receive and hold a semiconductor wafer 719 upon which the etching and deposition processes are performed. The chuck 717 can be an electrostatic chuck for supporting the wafer 719 when present. In some implementations, an edge ring (not shown) surrounds chuck 717, and has an upper surface that is approximately planar with a top surface of the wafer 719, when present over chuck 717. The chuck 717 also includes electrostatic electrodes for chucking and dechucking the wafer 719. A filter and DC clamp power supply (not shown) may be provided for this purpose. Other control systems for lifting the wafer 719 off the chuck 717 can also be provided. The chuck 717 can be electrically charged using an RF power supply 723. The RF power supply 723 is connected to matching circuitry 721 through a connection 727. The matching circuitry 721 is connected to the chuck 717 through a connection 725. In this manner, the RF power supply 723 is connected to the chuck 717. In various implementations, a bias power of the electrostatic chuck may be set at about 50 V or may be set at a different bias power depending on the process performed in accordance with disclosed implementations. For example, the bias power may be between about 20 Vb and about 100 V, or between about 30 V and about 150 V.

Elements for plasma generation include a coil 733 is positioned above window 711. In some implementations, a coil is not used in disclosed implementations. The coil 733 is fabricated from an electrically conductive material and includes at least one complete turn. The example of a coil 733 shown in FIG. 7 includes three turns. The cross sections of coil 733 are shown with symbols, and coils having an “X” extend rotationally into the page, while coils having a “⋅” extend rotationally out of the page. Elements for plasma generation also include an RF power supply 741 configured to supply RF power to the coil 733. In general, the RF power supply 741 is connected to matching circuitry 739 through a connection 745. The matching circuitry 739 is connected to the coil 733 through a connection 743. In this manner, the RF power supply 741 is connected to the coil 733. An optional Faraday shield 749a is positioned between the coil 733 and the window 711. The Faraday shield 749a may be maintained in a spaced apart relationship relative to the coil 733. In some implementations, the Faraday shield 749a is disposed immediately above the window 711. In some implementations, the Faraday shield 749b is between the window 711 and the chuck 717. In some implementations, the Faraday shield 749b is not maintained in a spaced apart relationship relative to the coil 733. For example, the Faraday shield 749b may be directly below the window 711 without a gap. The coil 733, the Faraday shield 749a, and the window 711 are each configured to be substantially parallel to one another. The Faraday shield 749a may prevent metal or other species from depositing on the window 711 of the process chamber 724.

Process gases may be flowed into the process chamber through one or more main gas flow inlets 760 positioned in the upper sub-chamber 702 and/or through one or more side gas flow inlets 770. Likewise, though not explicitly shown, similar gas flow inlets may be used to supply process gases to a capacitively coupled plasma processing chamber. A vacuum pump, e.g., a one or two stage mechanical dry pump and/or turbomolecular pump 740, may be used to draw process gases out of the process chamber 724 and to maintain a pressure within the process chamber 724. For example, the vacuum pump may be used to evacuate the lower sub-chamber 703 during a purge operation. A valve-controlled conduit may be used to fluidically connect the vacuum pump to the process chamber 724 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 700, one or more process gases may be supplied through the gas flow inlets 760 and/or 770. In certain implementations, process gas may be supplied only through the main gas flow inlet 760, or only through the side gas flow inlet 770. In some cases, the gas flow inlets shown in the figure may be replaced by more complex gas flow inlets, one or more showerheads, for example. The Faraday shield 749a and/or optional grid 750 may include internal channels and holes that allow delivery of process gases to the process chamber 724. Either or both of Faraday shield 749a and optional grid 750 may serve as a showerhead for delivery of process gases. In some implementations, a liquid vaporization and delivery system may be situated upstream of the process chamber 724, such that once a liquid reactant or precursor is vaporized, the vaporized reactant or precursor is introduced into the process chamber 724 via a gas flow inlet 760 and/or 770.

Radio frequency power is supplied from the RF power supply 741 to the coil 733 to cause an RF current to flow through the coil 733. The RF current flowing through the coil 533 generates an electromagnetic field about the coil 733. The electromagnetic field generates an inductive current within the upper sub-chamber 702. The physical and chemical interactions of various generated ions and radicals with the wafer 719 etch features of and selectively deposit layers on the wafer 719.

If the plasma grid 750 is used such that there is both an upper sub-chamber 702 and a lower sub-chamber 703, the inductive current acts on the gas present in the upper sub-chamber 702 to generate an electron-ion plasma in the upper sub-chamber 702. The optional internal plasma grid 750 limits the amount of hot electrons in the lower sub-chamber 703. In some implementations, the apparatus 700 is designed and operated such that the plasma present in the lower sub-chamber 703 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 703 through port 722. The chuck 717 disclosed herein may operate at elevated temperatures ranging between about 10° C. and about 250° C. The temperature will depend on the process operation and specific recipe.

Apparatus 700 may be coupled to facilities (not shown) when installed in a clean room or a fabrication facility. Facilities include plumbing that provide processing gases, vacuum, temperature control, and environmental particle control. These facilities are coupled to apparatus 700, when installed in the target fabrication facility. Additionally, apparatus 700 may be coupled to a transfer chamber that allows robotics to transfer semiconductor wafers into and out of apparatus 700 using typical automation.

In some implementations, a system controller 730 (which may include one or more physical or logical controllers) controls some or all of the operations of a process chamber 724. The system controller 730 may include one or more memory devices and one or more processors. In some implementations, the apparatus 700 includes a switching system for controlling flow rates and durations when disclosed implementations are performed. In some implementations, the apparatus 700 may have a switching time of up to about 500 ms, or up to about 750 ms. Switching time may depend on the flow chemistry, recipe chosen, reactor architecture, and other factors.

In some implementations, the system controller 730 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 730, which may control various components or subparts of the system or systems. The system controller 730, depending on the processing parameters and/or the type of system, may be programmed to control any of the processes disclosed herein, including the delivery of processing gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks connected to or interfaced with a specific system.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 8 depicts a semiconductor process cluster tool architecture with vacuum-integrated deposition, EUV patterning and dry development/etch modules that interface with a vacuum transfer module, suitable for implementation of the processes described herein. While the processes may be conducted without such vacuum integrated apparatus, such apparatus may be advantageous in some implementations.

FIG. 8 depicts a semiconductor process cluster tool architecture with vacuum-integrated deposition and patterning modules that interface with a vacuum transfer module, suitable for implementations of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 838 interfaces with four processing modules 820a-820d, which may be individually optimized to perform various fabrication processes. By way of example, processing modules 820a-820d may be implemented to perform deposition, evaporation, ELD, dry development, clean, etch, strip, and/or other semiconductor processes. For example, module 820a may be an ALD reactor that may be operated to perform in a non-plasma, thermal atomic layer depositions as described herein, such as Vector tool, available from Lam Research Corporation, Fremont, CA. And module 820b may be a PECVD tool, such as the Lam Vector®. It should be understood that the figure is not necessarily drawn to scale.

Airlocks 842 and 846, also known as a loadlocks or transfer modules, interface with the VTM 838 and a patterning module 840. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible implementation of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 8 but without the integrated patterning module.

Airlock 842 may be an “outgoing” loadlock, referring to the transfer of a substrate out from the VTM 838 serving a deposition module 820a to the patterning module 840, and airlock 846 may be an “ingoing” loadlock, referring to the transfer of a substrate from the patterning module 840 back in to the VTM 838. The ingoing loadlock 846 may also provide an interface to the exterior of the tool for access and egress of substrates. Each process module has a facet that interfaces the module to VTM 838. For example, deposition process module 820a has facet 836. Inside each facet, sensors, for example, sensors 1-18 as shown, are used to detect the passing of wafer 826 when moved between respective stations. Patterning module 840 and airlocks 842 and 846 may be similarly equipped with additional facets and sensors, not shown.

Main VTM robot 822 transfers wafer 826 between modules, including airlocks 842 and 846. In one implementation, robot 822 has one arm, and in another implementation, robot 822 has two arms, where each arm has an end effector 824 to pick wafers such as wafer 826 for transport. Front-end robot 844, in is used to transfer wafers 826 from outgoing airlock 842 into the patterning module 840, from the patterning module 840 into ingoing airlock 846. Front-end robot 844 may also transport wafers 826 between the ingoing loadlock and the exterior of the tool for access and egress of substrates. Because ingoing airlock module 846 has the ability to match the environment between atmospheric and vacuum, the wafer 826 is able to move between the two pressure environments without being damaged.

It should be noted that an EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 842 may provide this function by holding the transferred wafers at a lower pressure, no higher than the pressure in the patterning module 840, for a period of time and exhausting any off-gassing, so that the optics of the patterning module 840 are not contaminated by off-gassing from the substrate. A suitable pressure for the outgoing, off-gassing airlock is no more than 1E-8 Torr.

In some implementations, a system controller 850 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 850 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain implementations, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some implementations, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various implementations, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, developing the photopatterned resist, and etching the underlying layer or layer stack using the patterned resist as a mask.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIG. 5, 6, or 7 may be implemented with the tool in FIG. 8.

### CONCLUSION

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

1. A method of cleaning a process chamber, the method comprising:
providing, in the process chamber, a semiconductor substrate with a metal-containing resist film on a surface of the semiconductor substrate, wherein organometallic material is formed on one or more internal surfaces of the process chamber;
exposing, without the semiconductor substrate in the process chamber, the one or more internal surfaces of the process chamber to a non-plasma etch gas in the process chamber to remove first portions of the organometallic material; and
exposing, without the semiconductor substrate in the process chamber, the one or more internal surfaces of the process chamber to a first plasma to remove second portions of the organometallic material.

2. The method of claim 1, wherein exposing the one or more internal surfaces to the non-plasma etch gas converts unremoved portions of the organometallic material to a nonvolatile byproduct, wherein the second portions comprise the nonvolatile byproduct.

3. The method of claim 1, wherein the first plasma comprises a halide-containing plasma, a hydrogen-containing plasma, a hydrocarbon-containing plasma, an inert gas-containing plasma, or a combination thereof.

4. The method of claim 3, wherein the first plasma comprises a chlorine (Cl₂) plasma.

5. The method of claim 1, wherein the non-plasma etch gas comprises a hydrogen halide, boron tribromide, boron trichloride, or combinations thereof.

6. The method of claim 5, wherein the non-plasma etch gas comprises hydrogen chloride (HCl) or hydrogen bromide (HBr).

7. The method of claim 1, wherein introducing the non-plasma etch gas comprises:
heating the one or more internal surfaces of the process chamber to an elevated temperature, wherein the elevated temperature is between about −15° C. and about 200° C.; and
flowing the non-plasma etch gas into the process chamber.

8. The method of claim 1, further comprising:
exposing the one or more internal surfaces of the process chamber to a second plasma to remove one or both of residual gases and residual organic material from the process chamber.

9. The method of claim 8, wherein the second plasma comprises an oxygen-containing plasma or hydrogen-containing plasma.

10. The method of claim 1, wherein the first plasma is configured to form volatile products with the second portions of the organometallic material.

11. The method of claim 1, further comprising:
generating the first plasma in a remote plasma source coupled to the process chamber.

12. The method of claim 1, further comprising:
generating the first plasma directly in the process chamber.

13. The method of claim 1, wherein the metal-containing resist film comprises a metal oxide-containing EUV photoresist material.

14. The method of claim 1, wherein the organometallic material comprises at least tin oxide.

15. The method of claim 1, wherein providing the semiconductor substrate comprises depositing the metal-containing resist film on the surface of the semiconductor substrate in the process chamber.

16. The method of claim 1, wherein providing the semiconductor substrate comprises baking the metal-containing resist film on the surface of the semiconductor substrate in the process chamber.

17. The method of claim 1, wherein providing the semiconductor substrate comprises dry developing the metal-containing resist film on the surface of the semiconductor substrate in the process chamber.

18. A method of cleaning a process chamber, the method comprising:
providing, in the process chamber, a semiconductor substrate with a metal-containing resist film on a surface of the semiconductor substrate, wherein organometallic material is formed on one or more internal surfaces of the process chamber;
exposing, without the semiconductor substrate in the process chamber, the one or more internal surfaces of the process chamber to a first plasma in the process chamber to remove first portions of the organometallic material; and
exposing, without the semiconductor substrate in the process chamber, the one or more internal surfaces of the process chamber to a non-plasma etch gas to remove second portions of the organometallic material.

19. The method of claim 18, wherein exposing the one or more internal surfaces to the first plasma converts unremoved portions of the organometallic material to a nonvolatile byproduct, wherein the second portions comprise the nonvolatile byproduct.

20. A method of cleaning a process chamber, the method comprising:
providing, in the process chamber, a semiconductor substrate with a metal-containing resist film on a surface of the semiconductor substrate, wherein organometallic material is formed on one or more internal surfaces of the process chamber; and
exposing, without the semiconductor substrate in the process chamber, the one or more internal surfaces of the process chamber to a first plasma in the process chamber to remove at least a substantial portion of the organometallic material.

21. The method of claim 20, wherein the first plasma comprises a halide-containing plasma, a hydrogen-containing plasma, a hydrocarbon-containing plasma, an inert gas-containing plasma, or a combination thereof.

22. The method of claim 21, wherein the first plasma comprises Cl₂, CH₄, Ar, or a mixture thereof.

23. The method of claim 21, wherein the first plasma comprises HBr, Ar, or a mixture thereof.

24. The method of claim 21, wherein a chamber pressure of the process chamber during exposure to the first plasma is between about 1 mTorr and about 20 Torr.

25. The method of claim 21, further comprising:
exposing, without the semiconductor substrate in the process chamber, the one or more internal surfaces of the process chamber to a second plasma to remove one or both of residual gases and residual organic material from the process chamber.

26.-39. (canceled)
